(19) United States
(12) Patent Application Publication
(10) Pub. No.: US 2023/0085755 A1
(43) Pub. Date: Mar. 23, 2023

(54) DISPLAY APPARATUS AND METHOD OF MANUFACTURING DISPLAY APPARATUS

(71) Applicant: SAMSUNG DISPLAY CO., LTD., Yongin-si (KR)

(72) Inventors: Kyuho Jung, Yongin-si, Gyeonggi-do (KR); Wonjin Kim, Yongin-si, Gyeonggi-do (KR); Sangwon Lee, Yongin-si, Gyeonggi-do (KR)

(21) Appl. No.: 17/945,365

(22) Filed: Sep. 15, 2022

(30) Foreign Application Priority Data
Sep. 17, 2021 (KR) 10-2021-0125198

(51) Int. Cl. H01L 51/52; H01L 51/56

(52) U.S. Cl. CPC H01L 51/5246; H01L 51/56

(57) ABSTRACT

A display apparatus and a method of manufacturing a display apparatus are provided. The display apparatus includes: a display panel including at least one curved portion; a cover window covering one surface of the display panel; and a plurality of different adhesive members arranged between the display panel and the cover window. One of the plurality of different adhesive members is arranged to correspond to at least a portion of the curved portion of the display panel, and another of the plurality of different adhesive members is arranged to correspond to the rest of the display panel.

This application claims priority to Korean Patent Application No. 10-2021-0125198, filed on Sep. 17, 2021, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing a display apparatus, and more particularly, to a display apparatus including different adhesive members and a method of manufacturing a display apparatus.

### 2. Description of the Related Art

An electronic apparatus has been widely used. The electronic apparatus is variously used in mobile electronic apparatuses and stationary electronic apparatuses. To support various functions, the electronic apparatus includes a display apparatus that may provide a user with visual information such as images.

As other parts for driving the display apparatus are miniaturized recently, a portion of the display apparatus in the electronic apparatus has gradually increased, and a structure including two or more display areas extending at a preset angle has been also developed.

The above background art is technical information possessed by the inventor to derive the present disclosure or obtained during a process of deriving the present disclosure, and is not necessarily considered to be a known art open to the general public prior to the filing of the present disclosure.

### SUMMARY

One or more embodiments include a display apparatus including different adhesive members and a method of manufacturing a display apparatus, where a cover window is attached to a display panel by using the different adhesive members.

However, such a technical problem is an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes: a display panel including at least one curved portion; a cover window covering a first surface of the display panel; and a plurality of different adhesive members arranged between the display panel and the cover window, where one of the plurality of different adhesive members is arranged to correspond to at least a portion of the curved portion of the display panel, and another of the plurality of different adhesive members is arranged to correspond to a rest of the display panel.

The display panel may include: a main display area, subsidiary display areas, and corner display areas. The subsidiary display areas may be connected to sides of a periphery of the main display area, respectively, and the corner display area may be arranged between the subsidiary display areas. The plurality of different adhesive members may include a first adhesive member and a second adhesive member. The first adhesive member may be arranged in the main display area and the subsidiary display areas, and the second adhesive member may be arranged in the corner display areas.

The first adhesive member may surround the second adhesive member.

An injection hole may be arranged in one side of the first adhesive member, and the second adhesive member may be injected to the injection hole.

The second adhesive member and a portion of the first adhesive member may be arranged to correspond to the corner display area.

The first adhesive member may be arranged on a periphery of the corner display areas, and the second adhesive member may be arranged on a center of the corner display areas.

The first adhesive member and the second adhesive member may each be arranged in the same layer.

The corner display area may include a plurality of strip portions, and the second adhesive member may be arranged between the plurality of strip portions.

The display panel may include a main display area, subsidiary display areas, and corner display areas. The subsidiary display areas may be connected to sides of a periphery of the main display area, respectively, and the corner display area may be arranged between the subsidiary display areas. The plurality of different adhesive members may include a first adhesive member and a second adhesive member. The first adhesive member may be arranged in the main display area, and the second adhesive member may be arranged in the subsidiary display areas and the corner display areas.

Viscosity of the first adhesive member may be greater than viscosity of the second adhesive member.

The display apparatus may further include a thermoforming film arranged on a second surface of the display panel opposite to the first surface.

According to one or more embodiments, a method of manufacturing a display apparatus includes: arranging a plurality of different adhesive members between a cover window and a display panel; aligning the display panel such that one surface of the display panel on which the plurality of different adhesive members are arranged faces the cover window; and attaching the cover window to the display panel.

The arranging of the plurality of different adhesive members may include: arranging a first adhesive member of a solid type and arranging a second adhesive member of a liquid type. The plurality of different adhesive members may include the first adhesive member and the second adhesive member.

The display panel may include a main display area, subsidiary display areas, and corner display areas. The subsidiary display areas may be connected to sides of a periphery of the main display area, respectively, and the corner display area may be arranged between the subsidiary display areas. The arranging of the plurality of different adhesive members may include: arranging a first adhesive member in a portion of the main display area, the subsidiary display areas, and the corner display areas, and arranging a second adhesive member in a rest of the main display area, the subsidiary display areas, and the corner display areas. The plurality of different adhesive members may include the first adhesive member and the second adhesive member.

The arranging of the second adhesive member may include injecting the second adhesive member after arranging the first adhesive member, and attaching the cover window to the display panel.

The arranging of the second adhesive member may include coating the second adhesive member on a center of the corner display area surrounded by the first adhesive member after arranging the first adhesive member in a periphery of the corner display area.

The method may further include hardening temporarily the first adhesive member and the second adhesive member.

According to one or more embodiments, a method of manufacturing a display apparatus includes: arranging a plurality of different adhesive members between a cover window and a display panel; arranging a thermoforming film on a first surface of the display panel opposite to a second surface of the display panel that faces the cover window; transforming a shape of the display panel; aligning the display panel such that one surface of the display panel on which the plurality of different adhesive members are arranged faces the cover window; and attaching the cover window to the display panel.

The transforming of the shape of the display panel may include softening the thermoforming film by raising a temperature of the thermoforming film.

The arranging of the plurality of different adhesive members may include: arranging a first adhesive member in one region of the display panel before attaching the cover window to the display panel; and arranging a second adhesive member to a rest of the display area other than the one region after attaching the cover window to the display panel. The plurality of different adhesive members may include the first adhesive member and the second adhesive member.

The arranging of the plurality of different adhesive members may include arranging the plurality of different adhesive members on one side of the cover window.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of a display apparatus according to an embodiment;

FIGS. 2A to 2C are cross-sectional views of a display apparatus according to an embodiment;

FIG. 3 is a plan view of a display panel according to an embodiment;

FIG. 4 is an enlarged plan view of a portion of a display panel according to an embodiment;

FIG. 5 is a cross-sectional view of a display apparatus according to an embodiment;

FIG. 6 is an exploded perspective view of a display apparatus according to an embodiment;

FIG. 7 is a plan view of a display panel and an adhesive member according to an embodiment;

FIG. 8 is a plan view of a display panel and an adhesive member according to another embodiment;

FIGS. 9A to 9L are views showing a method of manufacturing a display apparatus according to an embodiment;

FIGS. 10A to 10C are views showing a method of manufacturing a display apparatus according to another embodiment;

FIG. 11 is an exploded perspective view of a display apparatus according to another embodiment;

FIGS. 12A to 12J are views showing a method of manufacturing a display apparatus according to another embodiment;

FIG. 13 is an exploded perspective view of a display apparatus according to still another embodiment;

FIGS. 14A and 14B are views showing a method of manufacturing a display apparatus according to still another embodiment; and

FIG. 15 is a view showing a method of manufacturing a display apparatus according to yet another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments of the present disclosure are described in detail with reference to the accompanying drawings. When description is made with reference to the drawings, like reference numerals are used for like or corresponding elements and repeated descriptions thereof are omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. That is, for example, intervening layers, regions, or components may be present.

Sizes of elements in the drawings may be exaggerated or reduced for convenience of explanation. For example, since sizes and thicknesses of elements in the drawings are arbitrarily illustrated for convenience of explanation, the disclosure is not limited thereto.

The x-direction, the y-direction and the z-direction are not limited to three axes of the rectangular coordinate system, and may be interpreted in a broader sense. For example, the x-direction, the y-direction, and the z-direction may be perpendicular to one another, or may represent different directions that are not perpendicular to one another.

In the case where a certain embodiment may be implemented differently, a specific process order may be performed in the order different from the described order. As an example, two processes that are successively described may be substantially simultaneously performed or performed in the order opposite to the order described.

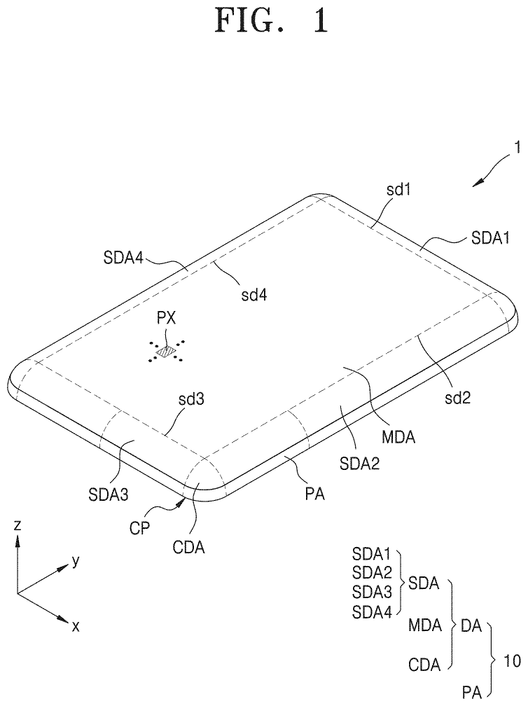

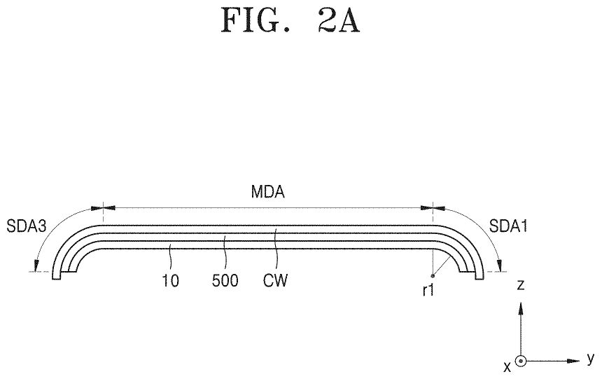

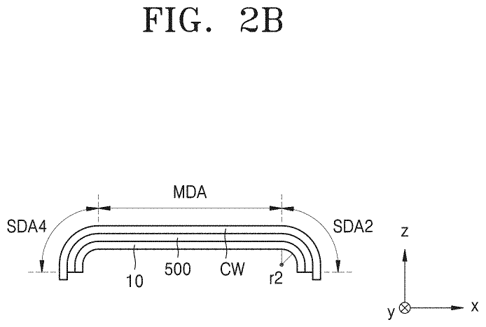

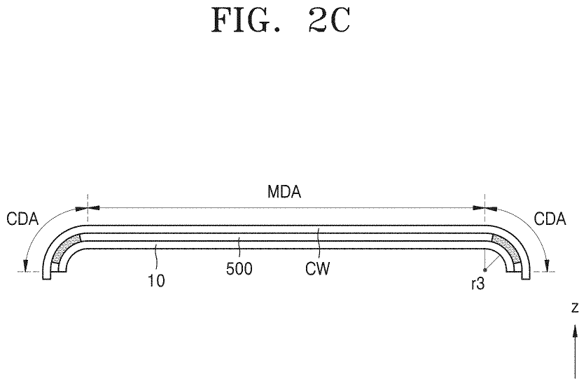

FIG. 1 is a perspective view of a display apparatus 1 according to an embodiment, and FIGS. 2A to 2C are cross-sectional views of the display apparatus 1 according to an embodiment. Specifically, FIG. 2A shows a cross-section of the display apparatus 1 taken along a y-direction of FIG. 1. FIG. 2B shows a cross-section of the display apparatus 1 taken along an x-direction. FIG. 2C shows a cross-section of corner display areas CDA arranged on two opposite sides of a main display area MDA in the display apparatus 1.

Referring to FIG. 1, the display apparatus 1 may include an apparatus for displaying moving images or still images and may be used as a display screen of various products including televisions, notebook computers, monitors, advertisement boards, Internet of things (“IoT”) device as well as portable electronic apparatuses including mobile phones, smartphones, tablet personal computers (“PC”), mobile communication terminals, electronic organizers, electronic books, portable multimedia players (“PMP”), navigations device, and ultra mobile personal computers (“UMPC”).

The display apparatus 1 may be used in wearable devices including smartwatches, watchphones, glasses-type displays, or head-mounted displays (“HMD”). In addition, the display apparatus 1 may be used as instrument panels for automobiles, center fascias for automobiles, or center information displays (“CID”) arranged on a dashboard, room mirror displays that replace side mirrors of automobiles, and displays arranged on the backside of front seats as entertainment for back seats of automobiles.

The display apparatus 1 may have long sides in a first direction (e.g., the y-direction in FIG. 1) and short sides in a second direction (e.g., the x-direction in FIG. 1). Here, the first direction may cross the second direction (e.g., the x-direction in FIG. 1). As an example, the first direction may form an acute angle with respect to the second direction. As another example, the first direction may form an obtuse angle or a right angle with respect to the second direction. Hereinafter, the case where the first direction (e.g., the y-direction in FIG. 1) forms a right angle with respect to the second direction (e.g., the x-direction in FIG. 1) is mainly described in detail.

As another example, the length of the display apparatus 1 in the first direction may be equal to the length of the display apparatus 1 in the second direction. As another example, the display apparatus 1 may have short sides in the first direction (e.g., the y-direction in FIG. 1) and long sides in the second direction (e.g., the x-direction in FIG. 1).

An edge where long sides extending in the first direction (e.g., the y-direction in FIG. 1) meet short sides extending in the second direction (e.g., the x-direction in FIG. 1) may be round with a preset curvature.

Referring to FIG. 1 and FIGS. 2A to 2C, the display apparatus 1 may include a display panel 10 and a cover window CW. The cover window CW may protect the display panel 10.

The cover window CW may be a flexible window. The cover window CW may protect the display panel 10 while easily warping according to external force without cracks and the like. The cover window CW may include sapphire or plastic. As an example, the cover window CW may include ultra-thin glass (“UTG”) or colorless polyimide (“CPI”). In an embodiment, the cover window CW may have a structure in which a flexible polymer layer is arranged on one side of a glass substrate or include only a polymer layer.

The display panel 10 may be arranged below the cover window CW. The display panel 10 may be attached to the cover window CW by an adhesive member 500 described below.

The display panel 10 may include a display area DA and a peripheral area PA surrounding the display area DA. The display area DA may include a plurality of pixels PX and be configured to display images by using the plurality of pixels PX. The plurality of pixels PX may each include sub-pixels. As an example, the plurality of pixels PX may each include a red sub-pixel, a green sub-pixel, and a blue sub-pixel. Alternatively, the plurality of pixels PX may each include a red sub-pixel, a green sub-pixel, a blue sub-pixel, and a white sub-pixel.

The display area DA may include a main display area MDA, a subsidiary display area SDA, and a corner display area CDA. The main display area MDA, the subsidiary display area SDA, and the corner display area CDA may each include the plurality of pixels PX. The plurality of pixels PX may be configured to display images.

As an example, the plurality of pixels PX in each of the main display area MDA, the subsidiary display area SDA, and the corner display area CDA may be configured to display independent images. As another example, the plurality of pixels PX in each of the main display area MDA, the subsidiary display area SDA, and the corner display area CDA may be configured to display portions of one image.

The main display area MDA is a flat display area and may include the pixels PX each including a display element. The main display area MDA may be configured to display most of an image.

The pixels PX each including a display element may be arranged also in the subsidiary display area SDA. The subsidiary display area SDA may be configured to display images by using the pixels PX. The subsidiary display area SDA may include a first subsidiary display area SDA1, a second subsidiary display area SDA2, a third subsidiary display area SDA3, and a fourth subsidiary display area SDA4. At least one of the first subsidiary display area SDA1, the second subsidiary display area SDA2, the third subsidiary display area SDA3, and the fourth subsidiary display area SDA4 may be omitted.

The first subsidiary display area SDA1 and the third subsidiary display area SDA3 may each be connected to the main display area MDA in the first direction (e.g., the y-direction). As an example, the main display area MDA may be connected to the first subsidiary display area SDA1 in a +y-direction, and the main display area MDA may be connected to the third subsidiary display area SDA3 in a −y direction. The first subsidiary display area SDA1 may be connected to a first side sd1 of the main display area MDA, and the third subsidiary display area SDA3 may be connected to a third side sd3 of the main display area MDA.

The first subsidiary display area SDA1 and the third subsidiary display area SDA3 may each be bent with an arbitrary curvature radius. As an example, the curvature radius of the first subsidiary display area SDA1 may be different from the curvature radius of the third subsidiary display area SDA3. As another example, the curvature radius of the first subsidiary display area SDA1 may be the same as the curvature radius of the third subsidiary display area SDA3. Hereinafter, the case where the curvature radius of the first subsidiary display area SDA1 and the curvature radius of the third subsidiary display area SDA3 are the same, which is a first curvature radius r1, is mainly described in detail. In addition, because the first subsidiary display area SDA1 is the same as or similar to the third subsidiary display area SDA3, the first subsidiary display area SDA1 is mainly described in detail.

The second subsidiary display area SDA2 and the fourth subsidiary display area SDA4 may each be connected to the main display area MDA in the second direction (e.g., the x-direction). As an example, the main display area MDA may be connected to the second subsidiary display area SDA2 in a +x-direction, and the main display area MDA may be connected to the fourth subsidiary display area SDA4 in a −x direction.

The second subsidiary display area SDA2 and the fourth subsidiary display area SDA4 may each be bent with an arbitrary curvature radius. As an example, the curvature radius of the second subsidiary display area SDA2 may be different from the curvature radius of the fourth subsidiary display area SDA4. As another example, the curvature radius of the second subsidiary display area SDA2 may be the same as the curvature radius of the fourth subsidiary display area SDA4. Hereinafter, the case where the curvature radius of the second subsidiary display area SDA2 and the curvature radius of the fourth subsidiary display area SDA4 are the same, which is a second curvature radius r2, is mainly described in detail. In addition, because the second subsidiary display area SDA2 is the same as or similar to the fourth subsidiary display area SDA4, the second subsidiary display area SDA2 is mainly described in detail.

In an embodiment, the first curvature radius r1 of the first subsidiary display area SDA1 may be different from the second curvature radius r2 of the second subsidiary display area SDA2. As an example, the first curvature radius r1 may be less than the second curvature radius r2. As another example, the first curvature radius r1 may be greater than the second curvature radius r2.

In another embodiment, the first curvature radius r1 of the first subsidiary display area SDA1 may be the same as the second curvature radius r2 of the second subsidiary display area SDA2. Hereinafter, the case where the first curvature radius r1 is greater than the second curvature radius r2 is mainly described in detail.

The corner display area CDA may extend and bend from the edge of the main display area MDA. The corner display area CDA may be arranged to correspond to a corner portion CP. Here, the corner portion CP is an edge of the display area DA and may be a portion where a long side of the display area DA in the first direction (e.g., the y-direction) meets a short side of the display area DA in the second direction (e.g., the x-direction).

The corner display area CDA may be arranged between the subsidiary display areas SDA adjacent to each other. As an example, the corner display area CDA may be arranged between the first subsidiary display area SDA1 and the second subsidiary display area SDA2. The corner display area CDA may be arranged between the second subsidiary display area SDA2 and the third subsidiary display area SDA3, between the third subsidiary display area SDA3 and the fourth subsidiary display area SDA4, or between the fourth subsidiary display area SDA4 and the first subsidiary display area SDA1. Accordingly, the subsidiary display area SDA and the corner display area CDA may be arranged to surround the main display area MDA and each be bent with an arbitrary curvature radius.

A third curvature radius r3 of the corner display area CDA is variable. As an example, in the case where the first curvature radius r1 of the first subsidiary display area SDA1 is different from the second curvature radius r2 of the second subsidiary display area SDA2, the third curvature radius r3 of the corner display area CDA may gradually vary within the range between the first curvature radius r1 and the second curvature radius r2.

In an embodiment, in the case where the first curvature radius r1 of the first subsidiary display area SDA1 is greater than the second curvature radius r2 of the second subsidiary display area SDA2, the third curvature radius r3 of the corner display area CDA may be gradually reduced in a direction from the first subsidiary display area SDA1 to the second subsidiary display area SDA2. As an example, the third curvature radius r3 of the corner display area CDA may be less than the first curvature radius r1 and greater than the second curvature radius r2.

In an embodiment, the display apparatus 1 may be configured to display images not only in the main display area MDA but the subsidiary display area SDA and the corner display area CDA. Accordingly, a portion of the display area DA in the display apparatus 1 may increase. In addition, the display apparatus 1 may be bent at the corner thereof and may have an improved aesthetic sense by including the corner display area CDA that displays images.

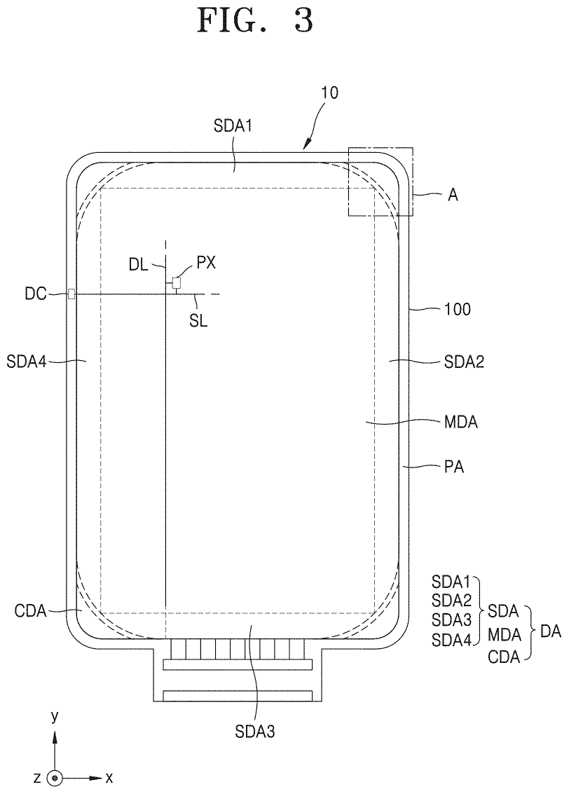

FIG. 3 is a plan view of the display panel 10 according to an embodiment.

Referring to FIG. 3, the display panel 10 may include display elements. As an example, the display panel 10 may be an organic light-emitting display panel that uses, as display elements, organic light-emitting diodes each including an organic emission layer. Alternatively, the display panel 10 may be a light-emitting diode display panel that uses light-emitting diodes LED. The size of the light-emitting diode LED may be micro scale or nano scale. Alternatively, the display panel 10 may be a quantum-dot light-emitting display panel that uses quantum-dot light-emitting diodes each including a quantum-dot emission layer. Alternatively, the display panel 10 may be an inorganic light-emitting display panel that uses inorganic light-emitting elements each including an inorganic semiconductor. Hereinafter, the case where the display panel 10 is an organic light-emitting display panel that uses organic light-emitting elements as display elements is mainly described in detail.

The display panel 10 may include the display area DA and the peripheral area PA. The display area DA is a region in which a plurality of pixels PX are configured to display images. The peripheral area PA is a region surrounding at least a portion of the display area DA. The display area DA may include the main display area MDA, the subsidiary display area SDA, and the corner display area CDA.

The pixels PX may each include sub-pixels. A sub-pixel is a display element and may emit light of a preset color by using an organic light-emitting element. In the present specification, the sub-pixel is a minimum unit implementing images and denotes an emission area.

The organic light-emitting element may emit, for example, red, green, or blue light. The organic light-emitting element may be connected to a pixel circuit including a thin-film transistor and a storage capacitor.

The display panel 10 may include a substrate 100 and a multi-layer arranged on the substrate 100. In this case, the display area DA and the peripheral area PA may be defined in the substrate 100 and/or the multi-layer. That is, the substrate 100 and/or the multi-layer may include the main display area MDA, the subsidiary display area SDA, and the corner display area CDA.

The substrate 100 may include glass or a polymer resin such as polyethersulfone, polyarylate, polyetherimide, polyethylene naphthalate, polyethylene terephthalate, polyphenylene sulfide, polyimide, polycarbonate, cellulose tri acetate, and cellulose acetate propionate. The substrate 100 including the polymer resin is flexible, rollable, and/or bendable. The substrate 100 may have a multi-layered structure including a base layer and a barrier layer (not shown), the base layer including the polymer resin.

The peripheral area PA may be a non-display area in which images are not displayed. A driving circuit DC or power wiring, and the like may be arranged in the peripheral area PA, the driving circuit DC providing electric signals to the pixels PX, and the power wiring providing power. The driving circuit DC may be arranged in the peripheral area PA, the driving circuit DC providing electric signals to each pixel PX through a signal line. As an example, the driving circuit DC may be a scan driving circuit configured to provide scan signals to each pixel PX through a scan line SL. Alternatively, the driving circuit DC may be a data driving circuit (not shown) configured to provide data signals to each pixel PX through a data line DL. In an embodiment, the data driving circuit may be adjacent to one side of the display panel 10. As an example, the data driving circuit may be arranged to a portion of the peripheral area PA that corresponds to the third subsidiary display area SDA3.

The peripheral area PA may include a pad portion (not shown) that is a region to which electronic elements, a printed circuit board, or the like may be electrically connected. The pad portion may be exposed and electrically connected to a flexible printed circuit board (“FPCB”) by not being covered by an insulating layer. The FPCB may electrically connect a controller to the pad portion and be configured to supply signals or power transferred from the controller. In an embodiment, the data driving circuit may be arranged in the FPCB.

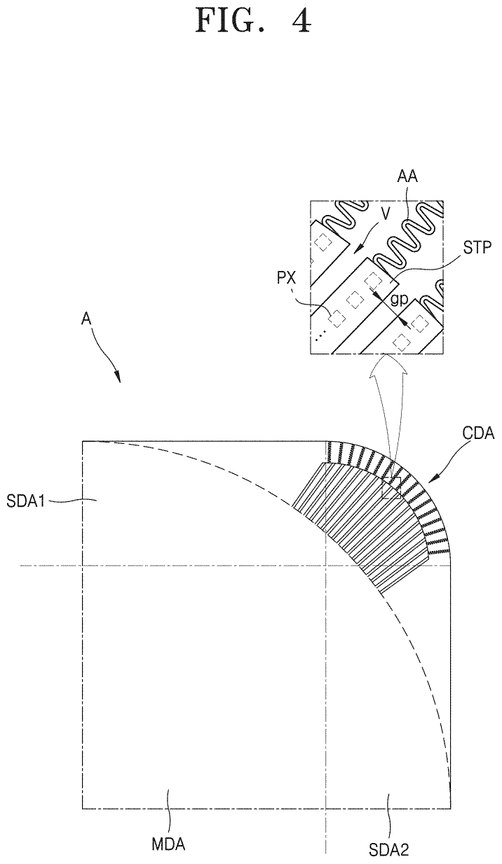

FIG. 4 is an enlarged plan view of a portion A of the display panel 10 according to an embodiment. Specifically, FIG. 4 shows an enlarged view of a corner display area CDA of the display panel 10 and shows a state before the display panel 10 is bent.

Referring to FIG. 4, the display panel 10 may include a plurality of strip portions STP, a plurality of auxiliary portions AA, and a plurality of through portions V corresponding to the corner display area CDA. The plurality of auxiliary portions AA may be connected to the ends of the plurality of strip portions STP, respectively. The plurality of through portions V may be arranged between the plurality of strip portions STP and may pass through the display panel 10.

Ends of the plurality of strip portions STP may be apart from each other with a preset gap gp therebetween. Empty spaces may be formed between the plurality of strip portions STP by the gaps gp and may correspond to the plurality of through portions V. The gaps gp between the plurality of strip portions STP may vary. As an example, as shown in FIG. 4, the gaps gp between the plurality of strip portions STP may widen from the main display area MDA toward the corner display area CDA. As another example, the gaps gp between the plurality of strip portions STP may be constant without varying. That is, the plurality of strip portions STP may be arranged radially or arranged in parallel to each other.

The other ends of the plurality of strip portions STP may be connected to each other without being apart from each other. As shown in FIG. 4, the plurality of strip portions STP may be connected to each other in a portion adjacent to the main display area MDA. In addition, the plurality of strip portions STP may each extend from the main display area MDA to the corner display area CDA, and the plurality of through portions V arranged between the plurality of strip portions STP may be formed. The extension lengths of the plurality of strip portions STP may be different from each other. The extension lengths of the plurality of strip portions STP may be different depending on a distance by which each of the plurality of strip portions STP is separated from the center of the corner display area CDA. As an example, among of the plurality of strip portions STP, the extension lengths of the strip portions STP arranged at the center of the corner display area CDA may be greater than the extension lengths of the other strip portions STP. As a distance by which each of the plurality of strip portions STP is separated from the center of the corner display area CDA increases, the extension length of each of the plurality of strip portions STP may be reduced.

Each through portion V may pass through the front surface and the lower surface of the display panel 10. Each through portion V may reduce the weight of the display panel 10 and improve the flexibility of the display panel 10. In addition, in the case where external force (warping, bending, or pulling force) is applied to the display panel 10, because the shapes of the through portions V change, stress occurring while the display panel 10 is transformed is easily reduced, and thus, abnormal transformation of the display panel 10 may be prevented and durability may be improved. Through this, user convenience may be improved when an electronic apparatus including the display panel 10 is used, and the display panel 10 may be easily applied to a wearable apparatus.

In the case where external force is applied to the display panel 10, the area or the shape of the through portion V may be changed and the position of the strip portion STP may be changed. As an example, in the case where force bending the edges of the display panel 10 and the corner sides therebetween is applied, as the gaps gp between the plurality of strip portions STP are reduced, the area of the through portion V may be reduced and the strip portions STP adjacent to each other may contact each other.

As described above, in the case where external force is applied to the display panel 10, the gaps gp between the plurality of strip portions STP, the area of the through portion V, or the like may change, and the shapes of the plurality of strips STP may not change. That is, the pixel circuit, the light-emitting element, or the like may be arranged on each of the plurality of strip portions STP, and even though external force is applied to the display panel 10, the shapes of the plurality of strip portions STP do not change, and thus, the pixel circuit, the light-emitting element, or the like arranged on each of the plurality of strip portions STP may be protected. The plurality of auxiliary portions AA may be connected to the ends of the plurality of strip portions STP and may extend in a direction away from the main display area MDA. The plurality of auxiliary portions AA may prevent the plurality of strip portions STP adjacent to each other from sticking to each other when the gaps gp between the plurality of strip portions STP change due to external force applied to the display panel 10. The plurality of auxiliary portions AA may be connected to the plurality of strip portions STP, respectively, and may hold the plurality of strip portions STP corresponding thereto. Due to the plurality of auxiliary portions AA, the plurality of strip portions STP adjacent to each other may not stick to each other and only the gaps gp between the plurality of strip portions STP may be reduced.

As described above, because the shapes of the plurality of strip portions STP may not change, the pixels PX may be arranged also in the corner display area CDA of the display panel 10 having a curvature. Through this, the display area DA (see FIG. 1) may extend from the main display area MDA and the subsidiary display area SDA to the corner display area CDA. The pixels PX arranged on the strip portions STP may be apart from each other in one direction. The pixels PX arranged on the strip portions STP may be arranged in various types such as, an s-stripe type, other stripe type, a PenTile® type, or the like.

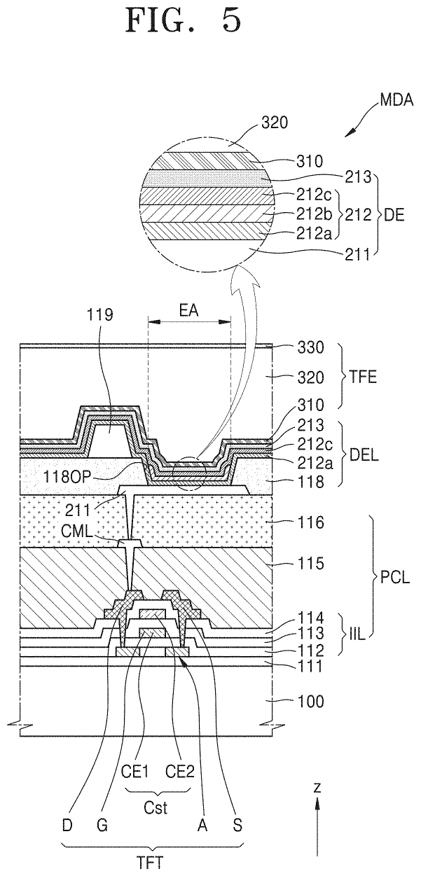

FIG. 5 is a cross-sectional view of the display apparatus 1 according to an embodiment. Specifically, FIG. 5 shows a cross-section of a pixel in the main display area of the display apparatus 1, and some members may be omitted. Hereinafter, a multi-layer stacked in the display apparatus 1 is described in detail with reference to FIG. 5.

Referring to FIG. 5, the display apparatus 1 may include the substrate 100, a buffer layer 111, a pixel circuit layer PCL, a display element layer DEL, and an encapsulation layer TFE.

The buffer layer 111 may include an inorganic insulating material such as silicon nitride, silicon oxynitride, and silicon oxide and include a single layer or a multi-layer including the inorganic insulating material.

The pixel circuit layer PCL may be arranged on the buffer layer 111. The pixel circuit layer PCL may include a thin-film transistor TFT and an inorganic insulating layer IIL, a first planarization layer 115, and a second planarization layer 116, where the thin-film transistor TFT may be included in the pixel circuit, and the inorganic insulating layer IIL, the first planarization layer 115, and the second planarization layer 116 may be arranged below and/or on elements of the thin-film transistor TFT. The inorganic insulating layer IIL may include a first gate insulating layer 112, a second gate insulating layer 113, and an interlayer insulating layer 114.

The thin-film transistor TFT may include a semiconductor layer A, and the semiconductor layer A may include polycrystalline silicon. Alternatively, the semiconductor layer A may include amorphous silicon, an oxide semiconductor, or an organic semiconductor. The semiconductor layer A may include a channel region, a drain region, and a source region, where the drain region and the source region may be disposed on two opposite sides of the channel region. A gate electrode G may overlap the channel region in a plan view.

The gate electrode G may include a low-resistance metal material. The gate electrode G may include a conductive material including molybdenum (Mo), aluminum (Al), copper (Cu), and/or titanium (Ti) and include a single layer or a multi-layer including the above materials.

The first gate insulating layer 112 between the semiconductor layer A and the gate electrode G may include an inorganic insulating material such as silicon nitride (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, may be ZnO or ZnO₂).

The second gate insulating layer 113 may cover the gate electrode G. Similar to the first gate insulating layer 112, the second gate insulating layer 113 may include an inorganic insulating material such as silicon nitride (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, may be ZnO or ZnO₂).

An upper electrode CE2 of the storage capacitor Cst may be arranged on the second gate insulating layer 113. The upper electrode CE2 may overlap the gate electrode G therebelow. In this case, the gate electrode G and the upper electrode CE2 overlapping each other with the second gate insulating layer 113 therebetween may constitute the storage capacitor Cst of the pixel circuit. That is, the gate electrode G may serve as a lower electrode CE1 of the storage capacitor Cst. Like this, the storage capacitor Cst may overlap the thin-film transistor TFT, in a plan view. In an embodiment, the storage capacitor Cst may be provided not to overlap the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu) and include a single layer or a multi-layer including the above materials.

The interlayer insulating layer 114 may cover the upper electrode CE2. The interlayer insulating layer 114 may include an inorganic insulating material such as silicon nitride (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, may be ZnO or ZnO₂). The interlayer insulating layer 114 may include a single layer or a multi-layer including the above inorganic insulating materials.

The drain electrode D and the source electrode S may each be arranged on the interlayer insulating layer 114. The drain electrode D and the source electrode S may each include a material having excellent conductivity. The drain electrode D and the source electrode S may each include a conductive material including molybdenum (Mo), aluminum (Al), copper (Cu), and titanium (Ti) and include a single layer or a multi-layer including the above materials. In an embodiment, the drain electrode D and the source electrode S may each have a multi-layered structure of Ti/Al/Ti.

The first planarization layer 115 may cover the drain electrode D and the source electrode S. The first planarization layer 115 may include an organic insulating material. The first planarization layer 115 may include an organic insulating material including a general-purpose polymer such as polymethylmethacrylate (“PMMA”) or polystyrene (“PS”), polymer derivatives having a phenol-based group, an acrylic-based polymer, an imide-based polymer, an aryl ether-based polymer, an amide-based polymer, a fluorine-based polymer, a p-xylene-based polymer, a vinyl alcohol-based polymer, or a blend thereof.

A connection electrode CML may be arranged on the first planarization layer 115. In this case, the connection electrode CML may be connected to the drain electrode D or the source electrode S through a contact hole of the first planarization layer 115. The connection electrode CML may include a material having excellent conductivity. The connection electrode CML may include a conductive material including molybdenum (Mo), aluminum (Al), copper (Cu), and/or titanium (Ti) and include a single layer or a multi-layer including the above materials. In an embodiment, the connection electrode CML may have a multi-layered structure of Ti/Al/Ti.

The second planarization layer 116 may cover the connection electrode CML. The second planarization layer 116 may include an organic insulating layer. The second planarization layer 116 may include an organic insulating material including a general-purpose polymer such as polymethylmethacrylate (“PMMA”) or polystyrene (“PS”), polymer derivatives having a phenol-based group, an acrylic-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be arranged on the pixel circuit layer PCL. The display element layer DEL may include a display element DE. The display element DE may be an organic light-emitting diode OLED. A pixel electrode 211 of the display element DE may be electrically connected to the connection electrode CML through a contact hole of the second planarization layer 116.

The pixel electrode 211 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 211 may further include a layer on/under the reflective layer, the layer including ITO, IZO, ZnO, or In₂O₃.

A pixel-defining layer 118 may be arranged on the pixel electrode 211, the pixel-defining layer 118 including an opening 1180P that exposes the central portion of the pixel electrode 211. The pixel-defining layer 118 may include an organic insulating material and/or an inorganic insulating material. The opening 1180P may define an emission area (referred to as an emission area EA, hereinafter) of light emitted from the display element DE. As an example, the width of the opening 1180P may correspond to the width of the emission area EA of the display element DE.

A spacer 119 may be arranged on the pixel-defining layer 118. The spacer 119 may be designed to prevent the destruction of the substrate 100 in a method of manufacturing a display apparatus. A mask sheet may be used while a display panel is manufactured. The mask sheet may enter the inside of the opening 1180P of the pixel-defining layer 118 or be closely attached to the pixel-defining layer 118. In this case, the spacer 119 may prevent defects in which a portion of the substrate 100 is damaged or destroyed by the mask sheet while deposition materials are deposited on the substrate 100.

The spacer 119 may include an organic insulating material such as polyimide. Alternatively, the spacer 119 may include an inorganic insulating material including silicon nitride or silicon oxide, or include an organic insulating material and an inorganic insulating material.

In an embodiment, the spacer 119 may include a material different from that of the pixel-defining layer 118. Alternatively, in another embodiment, the spacer 119 may include the same material as that of the pixel-defining layer 118. In this case, the pixel-defining layer 118 and the spacer 119 may be simultaneously formed during a mask process that uses a half-tone mask or the like.

An intermediate layer 212 may be arranged on the pixel-defining layer 118. The intermediate layer 212 may include an emission layer 212b arranged in the opening 1180P of the pixel-defining layer 118. The emission layer 212b may include a polymer organic material or a low-molecular weight organic material emitting light of a preset color.

A first functional layer 212a and a second functional layer 212c may be arranged under and on the emission layer 212b, respectively. The first functional layer 212a may include, for example, a hole transport layer (“HTL”), or include an HTL and a hole injection layer (“HIL”). The second functional layer 212c is an element arranged on the emission layer 212b and may be provided optionally. The second functional layer 212c may include an electron transport layer (“ETL”) and/or an electron injection layer (“EIL”). Like an opposite electrode 213 described below, the first functional layer 212a and/or the second functional layer 212c may be common layers covering the substrate 100 entirely.

The opposite electrode 213 may include a conductive material having a small work function. As an example, the opposite electrode 213 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), lithium (Li), calcium (Ca), or an alloy thereof. Alternatively, the opposite electrode 213 may further include a layer on the (semi) transparent layer including the above materials, the layer including ITO, IZO, ZnO, or In₂O₃.

In an embodiment, a capping layer (not shown) may be further arranged on the opposite electrode 213. The capping layer may include lithium fluoride (LiF), an inorganic material, and/or an organic material.

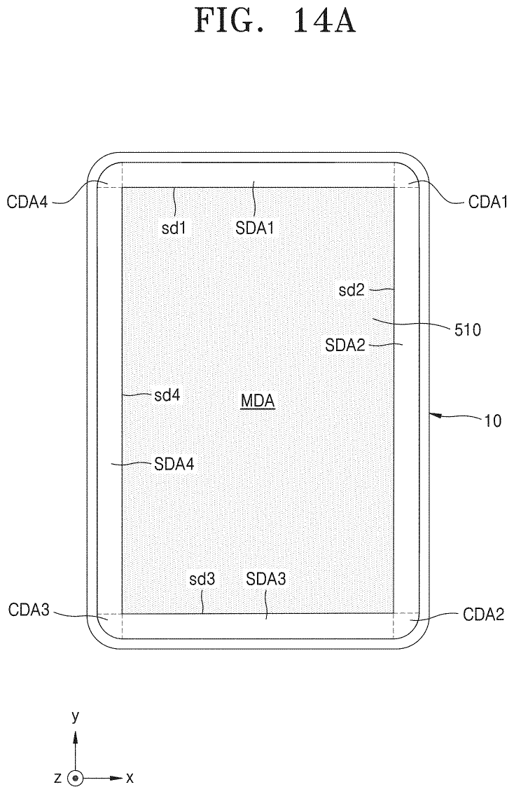

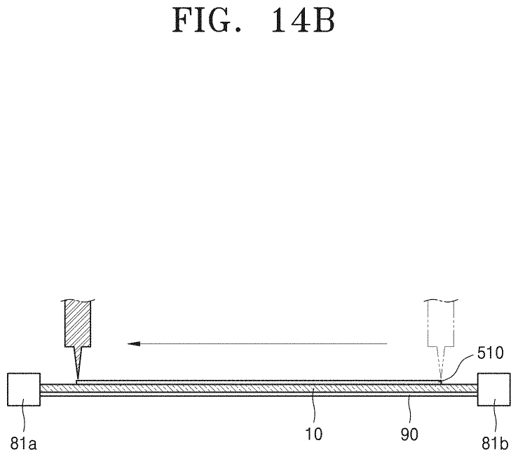

The encapsulation layer TFE may be arranged on the opposite electrode 213. In an embodiment, the encapsulation layer TFE may include at least one inorganic encapsulation layer and at least one organic encapsulation layer. It is shown in FIG. 14 that the encapsulation layer TFE includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic-based resin, an epoxy-based resin, polyimide, and/or polyethylene. In an embodiment, the organic encapsulation layer 320 may include acrylate.

Though not shown, a touch electrode layer may be arranged on the encapsulation layer TFE. An optical functional layer may be arranged on the touch electrode layer. The touch electrode layer may be configured to obtain coordinate information corresponding to an external input, for example, a touch event. The optical functional layer may reduce reflectivity of light (external light) incident toward the display apparatus from the outside and/or improve color purity of light emitted from the display apparatus. In an embodiment, the optical functional layer may include a retarder and/or a polarizer. The retarder may include a film-type retarder or a liquid crystal-type retarder. The retarder may include a λ/2 retarder and/or a λ/4 retarder. The polarizer may include a film-type polarizer or a liquid crystal-type polarizer. The film-type polarizer may include a stretched synthetic resin film, and the liquid crystal-type polarizer may include liquid crystals arranged in a predetermined arrangement. Each of the retarder and the polarizer may further include a protective film.

In another embodiment, the optical functional layer may include a black matrix and color filters. The color filters may be arranged by taking into account colors of pieces of light emitted from the pixels of the display apparatus, respectively. The color filters may each include red, green, or blue pigment or dye. Alternatively, the color filters may each further include quantum dots in addition to the pigment or dye. Alternatively, some of the color filters may not include the pigment or dye and may include scattering particles including such as titanium oxide.

In another embodiment, the optical functional layer may include a destructive interference structure. The destructive interference structure may include a first reflection layer and a second reflection layer arranged on different layers, respectively. First-reflected light and second-reflected light reflected by the first reflection layer and the second reflection layer, respectively, may destructively interfere and thus the reflectivity of external light may be reduced.

An adhesive member may be arranged between the touch electrode layer and the optical functional layer. For the adhesive member, a general one known in the art may be employed without limitation. The adhesive member may be a pressure sensitive adhesive (“PSA”).

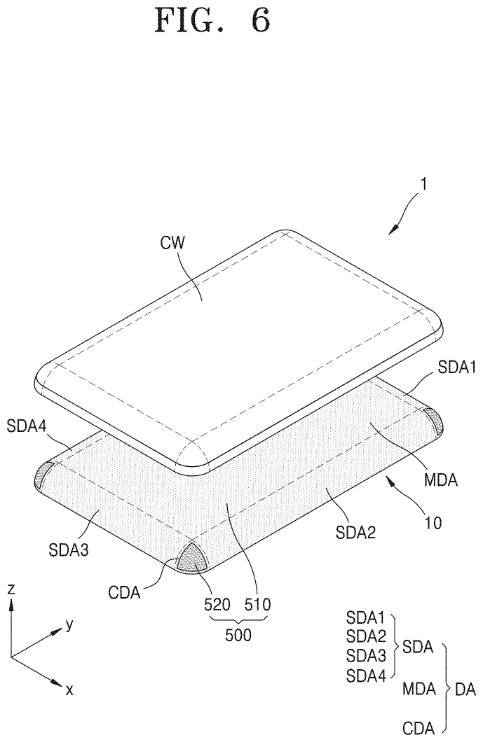

FIG. 6 is an exploded perspective view of a display apparatus 1 according to an embodiment.

Referring to FIG. 6, an adhesive member 500 may be arranged between the display panel 10 and the cover window CW. The adhesive member 500 may include an adhesive material that may attach the display panel 10 to the cover window CW. The adhesive member 500 may be provided in plurality. The plurality of adhesive members 500 may be different from each other.

In an embodiment, the adhesive member 500 may include a first adhesive member 510 and a second adhesive member 520 that is different from the first adhesive member 510.

The first adhesive member 510 may be arranged to correspond to a flat portion of one side (a side in a +z-direction of FIG. 6) of the display panel 10, for example, the main display area MDA. In addition, the first adhesive member 510 may be arranged to correspond to a portion of a curved portion of one side of the display panel 10, for example, the subsidiary display area SDA. That is, the first adhesive member 510 may be arranged in a region excluding the corner display area CDA. The second adhesive member 520 may be arranged to correspond to a portion of a curved portion of one side (a side in the +z-direction of FIG. 6) of the display panel 10, for example, the corner display area CDA.

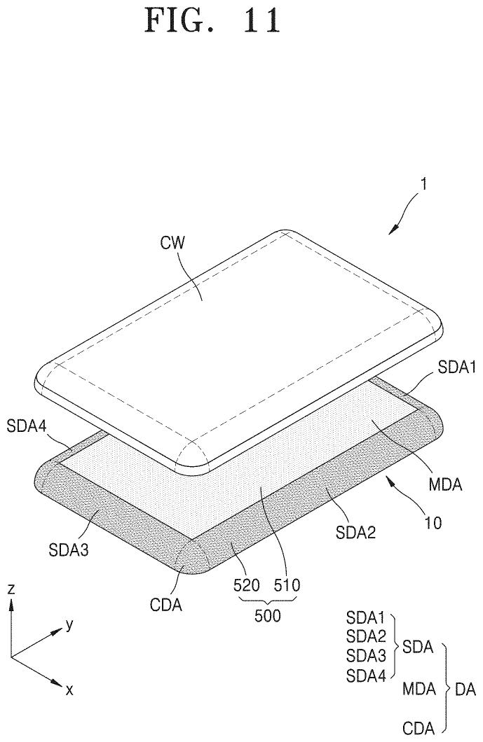

Though it is described in the present embodiment (See FIG. 6) as an example that the first adhesive member 510 is arranged in the main display area MDA and the subsidiary display area SDA, and the second adhesive member 520 is arranged in the corner display area CDA, in another embodiment, the first adhesive member 510 may be arranged in the main display area MDA, and the second adhesive member 520 may be arranged in the subsidiary display area SDA and the corner display area CDA as described below (See FIG. 11). Hereinafter, for convenience of description, the case where the first adhesive member 510 is arranged in the main display area MDA and the subsidiary display area SDA, and the second adhesive member 520 is arranged in the corner display area CDA is mainly described below.

In an embodiment, the first adhesive member 510 may be a solid or semi-solid optically clear adhesive (“OCA”) film. In addition, the second adhesive member 520 may be a liquid optically clear resin (“OCR”). In this case, the first adhesive member 510 may include at least one of an acrylic-based material, a silicon-based material, and a urethane-based material. The second adhesive member 520 may include at least one of an acrylic-based material, a silicon-based material, and a urethane-based material, and have a component or a composition different from that of the first adhesive member 510. Accordingly, the first adhesive member 510 may be different from the second adhesive member 520 not only in its phase but in its component or composition. A difference between the component or composition of the first adhesive member 510 and the component or composition of the second adhesive member 520 may be identified by, for example, a Fourier transform infra-red spectroscopy (“FT-IR”). In the case where the first adhesive member 510 is different from the second adhesive member 520 in its component or composition, a ratio of a peak height of frequencies may be different during spectroscopy.

In this case, the first adhesive member 510 may be an adhesive film that is formed as one body to cover both the main display area MDA and the subsidiary display area SDA. In addition, the second adhesive member 520 may fill the corner display area CDA.

Accordingly, bubbles or wrinkles may not occur between the display panel 10 and the cover window CW in the corner display area CDA of the display apparatus 1. Specifically, because the curvature radius of the corner display area CDA is variable as described above, there is possibility that bubbles or wrinkles occur due to overlapping, pre-adhesion, or the like while the corner display area CDA is attached to the cover window CW. However, in present embodiment, since the second adhesive member 520 arranged in the corner display area CDA may be liquid different from the first adhesive member 510, the second adhesive member 520 may freely move while the corner display area CDA is attached to the cover window CW.

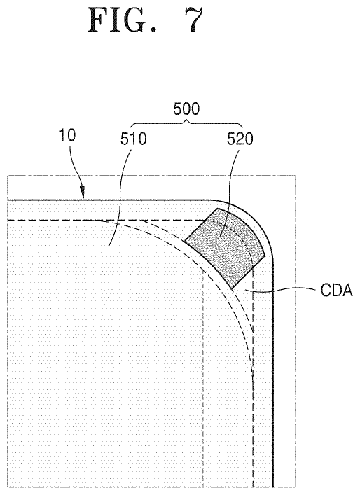

FIG. 7 is a plan view of the display panel 10 and an adhesive member according to an embodiment. Specifically, FIG. 7 is an enlarged view of the corner display area CDA of the display panel 10 of FIG. 6 and shows the display panel 10 that is not bent, for convenience of description.

Referring to FIG. 7, in an embodiment, the first adhesive member 510 may be arranged to surround the second adhesive member 520. That is, the first adhesive member 510 may surround the second adhesive member 520 in a plan view in a direction (e.g., a (−) z-direction of FIG. 7). In this case, the first adhesive member 510 may be arranged in the same layer as the second adhesive member 520. This means that the cover window CW is arranged on one side (the z-direction of FIG. 7) of both the first adhesive member 510 and the second adhesive member 520, and the display panel 10 is arranged on another side (the (−) z-direction of FIG. 7) opposite the one side. In other words, the second adhesive member 520 is not disposed on the first adhesive member 510.

In an embodiment, the first adhesive member 510 may be arranged on the periphery of the corner display area CDA. The first adhesive member 510 may extend from the periphery of the corner display area CDA to the subsidiary display area SDA and the main display area MDA. In addition, the second adhesive member 520 may be arranged in a space of the corner display area CDA formed by the first adhesive member 510, for example, the center of the corner display area CDA.

As described above, because the second adhesive member 520 is arranged inside the periphery formed by the first adhesive member 510, the second adhesive member 520, which is liquid, may be arranged without flowing during a process of manufacturing the display apparatus 1. This may allow the corner display area CDA to be attached to the cover window CW without separation.

In addition, in an embodiment, the second adhesive member 520 may be arranged between the plurality of strip portions STP (see FIG. 4) of the corner display area CDA. Accordingly, not only a result that the corner display area CDA may be attached to the cover window CW by the second adhesive member 520 without an empty space but also a result that a visibility deterioration issue in which a difference in a refractive index of light occurs due to an empty space between the strip portions STP may be resolved may be obtained.

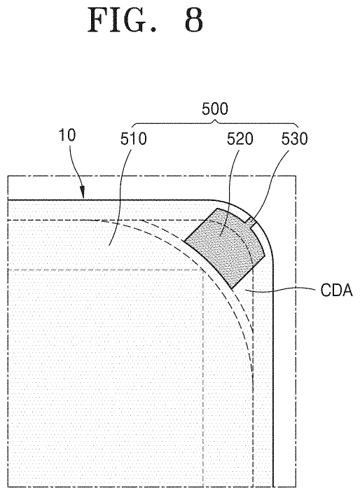

FIG. 8 is a plan view of the display panel 10 and the adhesive member 500 according to another embodiment.

Referring to FIG. 8, in the present embodiment, since an injection hole 530 may be arranged in one side of the first adhesive member 510 surrounding the second adhesive member 520, the second adhesive member 520 may be injected through the injection hole 530. Here, the one side of the first adhesive member 510 may be, for example, a side of the main display area MDA facing the corner display area CDA. As described below, the second adhesive member 520 may be injected into the periphery through the injection hole 530 by an injection tool such as a needle, and therefore, the periphery may be formed by the first adhesive member 510.

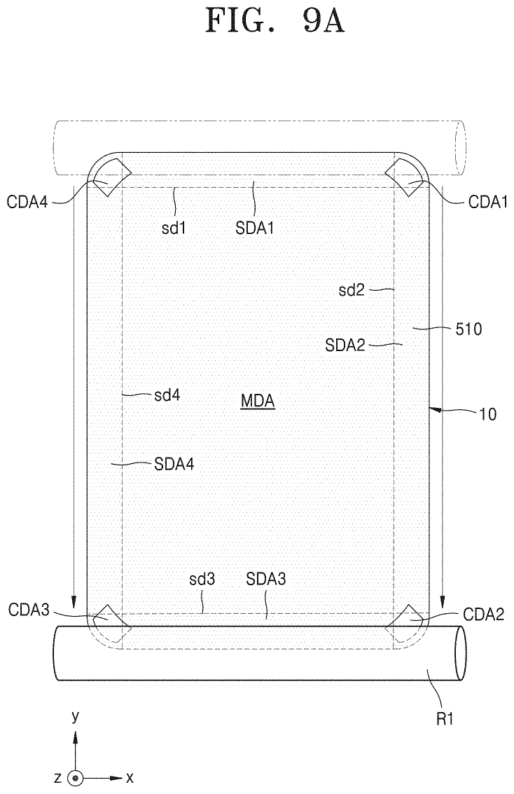

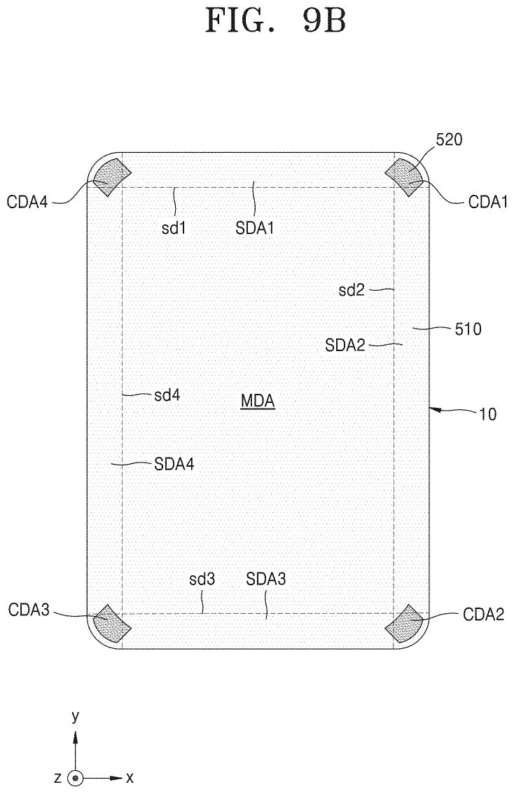

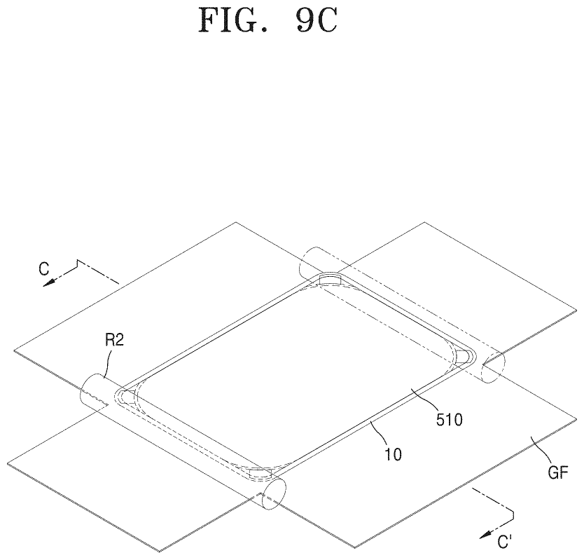

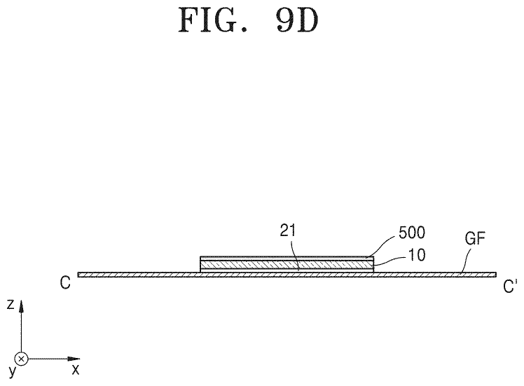

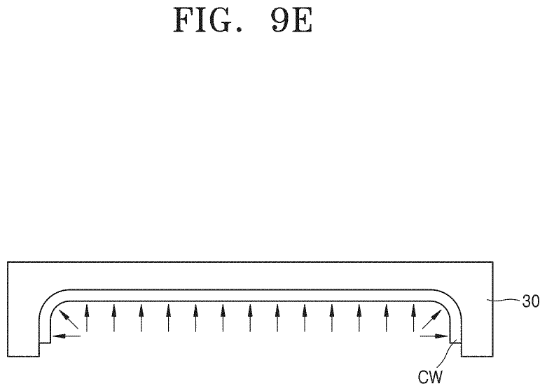

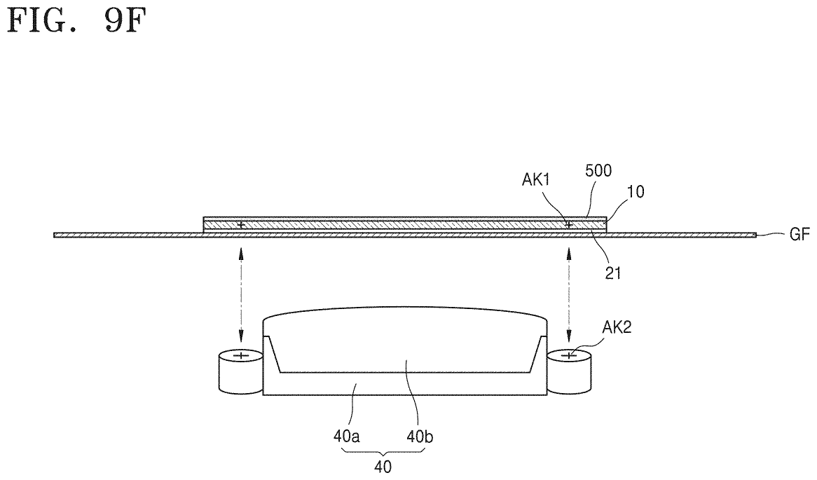

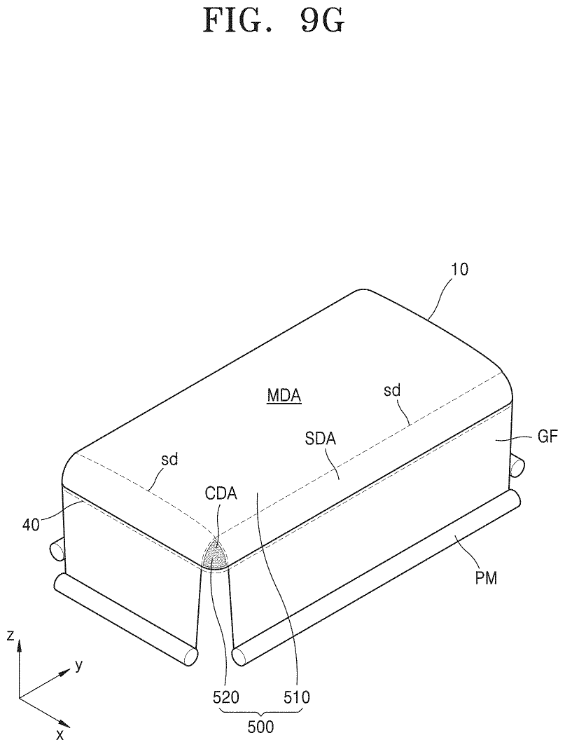

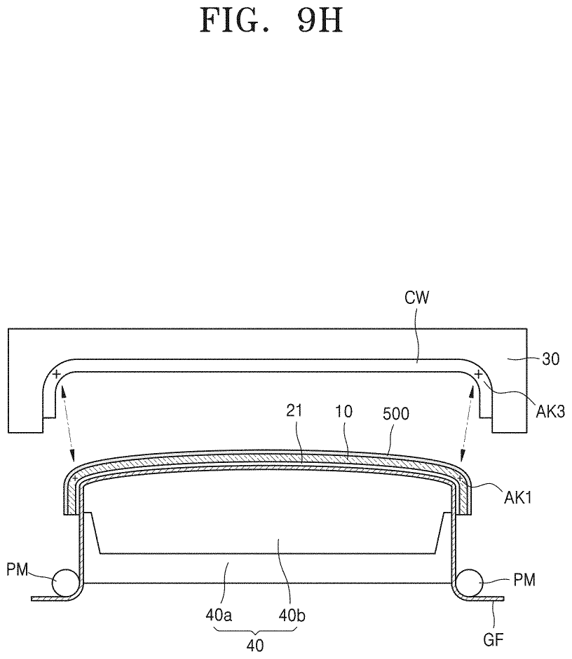

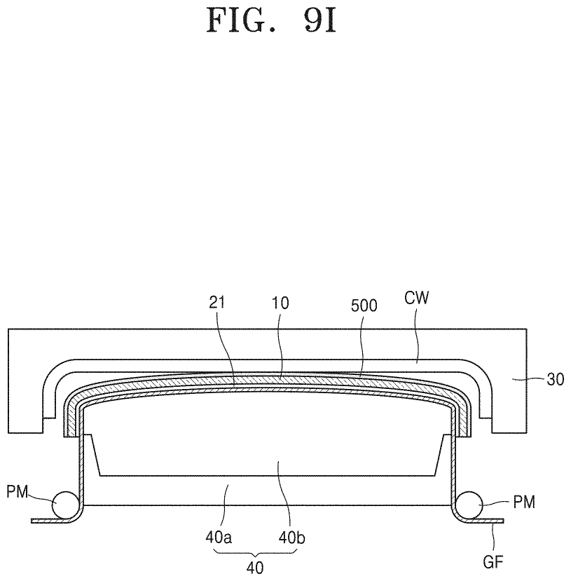

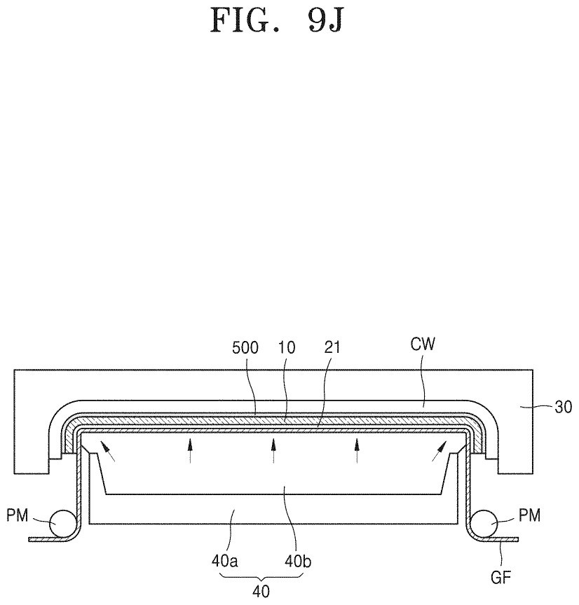

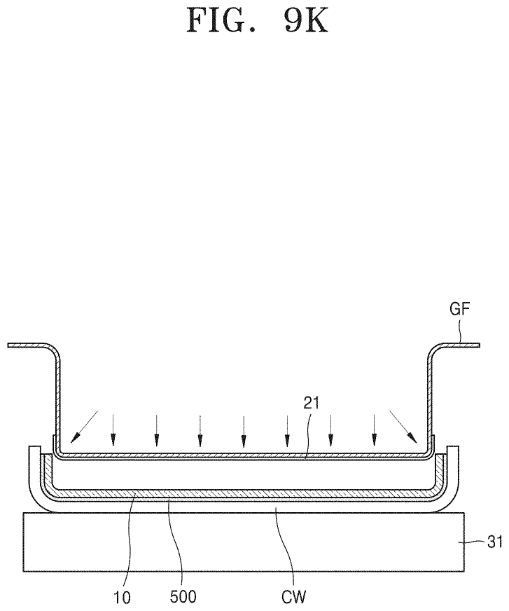

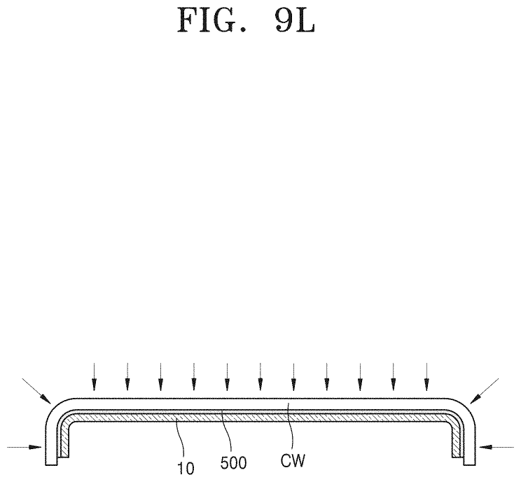

FIGS. 9A to 9L are views showing a method of manufacturing a display apparatus according to an embodiment.

Though the method of manufacturing a display apparatus according to an embodiment may be a method of manufacturing the display apparatus 1 described above, the method according to the invention is not limited thereto.

Referring to FIG. 9A, the first adhesive member 510 is attached on the front side (e.g., a side in a z-direction of FIG. 9A) of the display panel 10. In an embodiment, the first adhesive member 510 may be the first adhesive member 510 described above, particularly, the first adhesive member 510 shown in FIG. 7. As described above, the first adhesive member 510 may be a solid or semi-solid OCA film. As an example, the first adhesive member 510 may include an acrylic-based OCA film. As another example, the first adhesive member 510 may include a silicon-based OCA film.

The first adhesive member 510 may be attached to the main display area MDA and the subsidiary display area SDA. In this case, the first adhesive member 510 may be arranged also on the periphery of the corner display area CDA. That is, the first adhesive member 510 may not be arranged on the center of the corner display area CDA.

When attaching the first adhesive member 510 to the front side of the display panel 10, a first roller R1 may be used. While moving in a first direction (e.g., a direction progressing from the upper end of the display panel 10 to the lower end), the first roller R1 may be configured to apply pressure to the first adhesive member 510 such that the first adhesive member 510 is attached well to the display panel 10.

Referring to FIG. 9B, next, the second adhesive member 520 may be coated on the front side (e.g., a surface in the z-direction of FIG. 9B) of the display panel 10. As described above, the second adhesive member 520 may be a liquid OCR. As an example, the second adhesive member 520 may include an acrylic-based OCR. As another example, the second adhesive member 520 may include a silicon-based OCR.

In this case, the second adhesive member 520 may be coated on a space of the corner display area CDA formed inside the periphery of the first adhesive member 510, particularly, on the corner display area CDA by a tool such as a needle. Because the second adhesive member 520 is liquid, the second adhesive member 520 may be coated in the corner display area CDA without remaining an empty space, and coated also between the strip portions STP (see FIG. 4).

In an embodiment, the second adhesive member 520 may be coated and hardened temporarily. Temporary hardening means making the second adhesive member 520 in a higher viscosity state than the viscosity of liquid by hardening the second adhesive member 520 more or less in advance, for example, a state such as gel. In an embodiment, temporary hardening may be performed by irradiating an ultraviolet ray.

Next, referring to FIGS. 9C and 9D, a step of attaching a guide film GF to the backside (e.g., a surface in the (−) z-direction of FIG. 9C) of the display panel 10 while the first adhesive member 510 and the second adhesive member 520 are attached on the front side of the display panel 10 is performed. Here, FIG. 9D is a view of the guide film GF and the display panel 10 of FIG. 9C, taken along line C-C′.

Referring to FIG. 9D, an adhesive layer 21 may be arranged between the backside of the display panel 10 and the guide film GF. The backside of the display panel 10 may be attached to the guide film GF by the adhesive layer 21. The adhesive layer 21 may include, for example, a silicon-based OCA. Referring to FIG. 9C, a second roller R2 may be used to press the display panel 10 to be attached to the guide film GF.

Referring to FIG. 9E, the cover window CW is prepared. The step of preparing the cover window CW may include transforming the cover window CW using a jig 30 including a bending portion such that the cover window CW has a bent part. The jig 30 may correspond to a frame having the shape of the display apparatus to be finally manufactured. The shape of the cover window CW may be transformed to the shape of the inside of the jig 30 by closely attaching the cover window CW in the jig 30.

Referring to FIGS. 9F to 9G, the shape of the display panel 10 is transformed by applying external force to the guide film GF. Accordingly, the display panel 10 is preliminarily formed. In this case, the adhesive member 500 arranged on the display panel 10 may be also preliminarily formed together with the display panel 10.

First, as shown in FIG. 9F, the display panel 10 to which the guide film GF is attached is arranged such that the backside of the display panel 10 faces a pad portion 40, and then the display panel 10 is aligned to the pad portion 40. The display panel 10 is aligned to the pad portion 40 such that a first align key AK1 marked in the display panel 10 coincides with a second align key AK2 marked in the pad portion 40.

Next, as shown in FIG. 9G, the guide film GF attached to the backside of the display panel 10 is seated on the pad portion 40. A push member PM may be arranged on the guide film GF. The guide film GF is closely attached to the lateral surface of the pad portion 40 by using the push member PM. As a result, the display panel 10 may be preliminarily formed to the shape matching with the cover window CW.

The guide film GF may be bent by external force applied to the guide film GF. In the case where the guide film GF is transformed by the external force, the shape of the display panel 10 attached to the guide film GF may be also transformed together therewith. As an example, as shown in FIG. 9G, the subsidiary display area SDA and the corner display area CDA of the display panel 10 may each be transformed to have a curvature. Particularly, the corner display area CDA may contract while the subsidiary display areas SDA adjacent to the corner display area CDA are bent. In this case, because the second adhesive member 520 coated in the corner display area CDA is liquid, the second adhesive member 520 is not affected by bubbles occurred due to transformation of the corner display area CDA.

The display panel 10 is preliminarily formed, and then as shown in FIGS. 9H to 9J, the cover window CW is attached to the display panel 10.

First, as shown in FIG. 9H, the display panel 10 is arranged such that the front side of the display panel 10 faces the cover window CW, and then, the display panel 10 is aligned to the cover window CW. The display panel 10 is aligned to the cover window CW such that the first align key AK1 marked in the display panel 10 coincides with a third align key AK3 marked in the cover window CW.

Next, as shown in FIGS. 9I and 9J, the cover window CW may be attached to the display panel 10 by using the pad portion 40.

First, as shown in FIG. 9I, a portion of the main display area MDA (see FIG. 9A), which is the central portion of the display panel 10, may be attached to the cover window CW. In the final shape of the display panel 10, a flat surface (e.g., the main display area MDA) having no curvature may first be attached to the cover window CW.

In addition, as shown in FIG. 9J, the cover window CW may be attached to the subsidiary display area SDA (see FIG. 9A) and the corner display area CDA (see FIG. 9A) of the display panel 10 each having a curvature. A step of attaching the cover window CW to the subsidiary display area SDA and a step of attaching the cover window CW to the corner display area CDA may be performed simultaneously. As an example, while the subsidiary display area SDA is attached to the cover window CW, the corner display area CDA may be naturally attached to the cover window CW by peripheral external force. As another example, a step of attaching the subsidiary display area SDA to the cover window CW and a step of attaching the corner display area CDA to the cover window CW may be performed at different timings. As an example, the subsidiary display area SDA may first be attached to the cover window CW, and then, the corner display area CDA may be attached to the cover window CW.

The pad portion 40 may include a first pad portion 40a and a second pad portion 40b. The first pad portion 40a may be a jig supporting the second pad portion 40b. The second pad portion 40b may include an air pump or be connected to an air pump. The second pad portion 40b has a low modulus, and thus, the shape and the volume of the second pad portion 40b may vary according to air pressure through the air pump. The second pad portion 40b may include a diaphragm.

With the adhesive member 500 being in contact with the cover window CW, the display panel 10 may be attached to the cover window CW by applying pressure through the second pad portion 40b.

While the cover window CW is attached to the display panel 10, the subsidiary display areas SDA adjacent to the corner display area CDA may be bent and contracted. In this case, because the second adhesive member 520 coated in the corner display area CDA is liquid, the second adhesive member 520 may not be affected by bubbles or the like occurred due to transformation of the corner display area CDA. Accordingly, the display panel 10, particularly, the corner display area CDA may be suitably attached to the cover window CW.

A step of attaching the display panel 10 to the cover window CW is performed, and then, the display panel 10 to which the cover window CW is attached may be separated from the jig 30 and the pad portion 40.

Next, as shown in FIG. 9K, the display panel 10 to which the cover window CW is attached is turned over 180° and arranged on a carrier shuttle 31. As another example, a next process may be performed without turning over the display panel 10.

Referring to FIG. 9K, a step of separating the guide film GF from the display panel 10 is performed. As an example, in the case where the adhesive layer 21 configured to attach the guide film GF to the display panel 10 is implemented as an ultraviolet adhesive sheet, the guide film GF may be separated from the display panel 10 by irradiating an ultraviolet ray to the adhesive layer 21. As an example, because an ultraviolet ray is irradiated to the adhesive layer 21, adhesive force between the adhesive layer 21 and the display panel 10 relatively weakens, and thus, the guide film GF may be separated from the display panel 10. Though it is shown in FIG. 9K that adhesive force between the adhesive layer 21 and the display panel 10 relatively weakens and the adhesive layer 21 remains on the guide film GF, adhesive force between the adhesive layer 21 and the guide film GF may relatively weaken. In this case, the adhesive layer 21 may remain on the display panel 10.

The guide film GF is separated from the display panel 10, and then, referring to FIG. 9L, a step of hardening the cover window CW and the display panel 10 attached to each other is performed. As an example, the hardening may be performed by irradiating an ultraviolet ray to the cover window CW and the display panel 10. In this case, the adhesive member 500 may be hardened, and when high temperature and/or high pressure are applied to the cover window CW and the display panel 10, bubbles or the like formed inside the adhesive member 500 may come out.

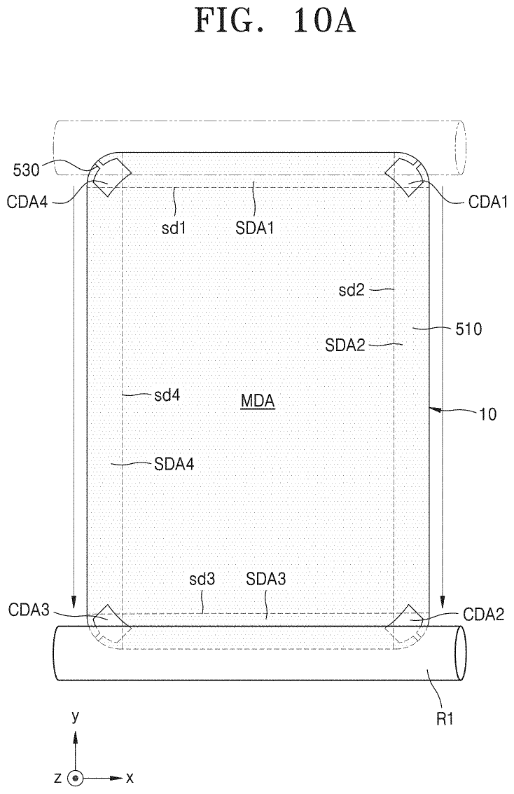

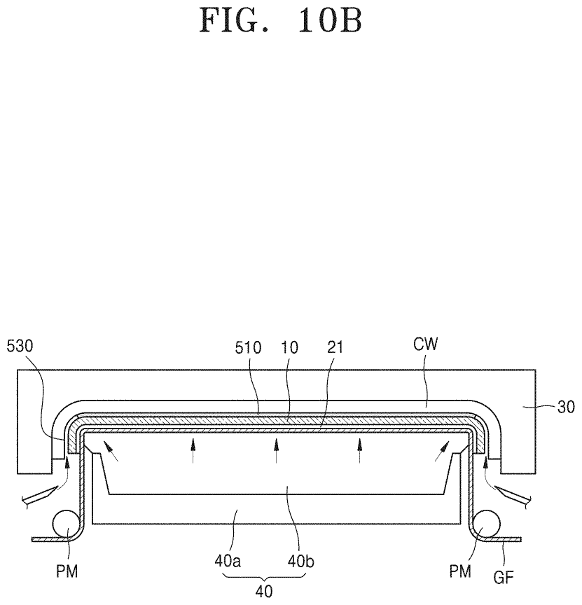

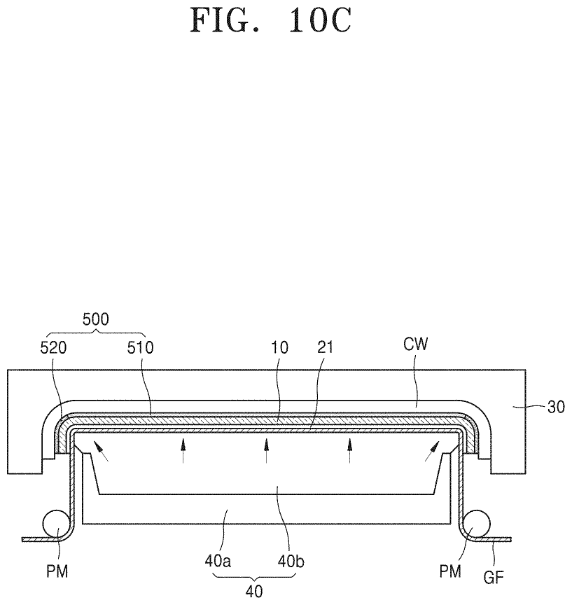

FIGS. 10A to 10C are views showing a method of manufacturing a display apparatus according to another embodiment. The method of manufacturing a display apparatus according to an embodiment may be a method of manufacturing a modified embodiment (see FIG. 8) of the display apparatus 1 (see FIG. 1) described above. Because the present method is similar to the method of manufacturing a display apparatus described above with reference to FIG. 9, differences are mainly described below.

Referring to FIG. 10A, the first adhesive member 510 is attached to the front side (e.g., a side in a z-direction of FIG. 10A) of the display panel 10. In an embodiment, the first adhesive member 510 may be the first adhesive member 510 described above, particularly, the first adhesive member 510 shown in FIG. 8.

The first adhesive member 510 may be attached to the main display area MDA and the subsidiary display area SDA. The first adhesive member 510 may be attached also to the periphery of the corner display area CDA. In this case, the injection hole 530 may be provided in one side of the first adhesive member 510, and the second adhesive member 520 may be injected to the injection hole 530. Here, one side of the first adhesive member 510 may be, for example, a side of the main display area MDA facing the corner display area CDA.

After the first adhesive member 510 is attached, the second adhesive member 520 may not be coated, and the display panel 10 may be attached to the cover window CW in accordance with FIGS. 9C to 9J. That is, the guide film GF is attached to the backside of the display panel 10, the cover window CW is prepared, and the shape of the display panel 10 may be transformed by applying external force to the guide film GF. In addition, the display panel 10 is aligned to the cover window CW, and the display panel 10 may be attached to the cover window CW by using the pad portion 40 and the jig 30.

In this case, because the second adhesive member 520 is not coated in the corner display area CDA, the main display area MDA and the subsidiary display area SDA except the corner display area CDA may be attached to the cover window CW.

FIGS. 10B and 10C are cross-sectional views showing a process of attaching the display panel 10 to the cover window CW when viewed in the same direction as that of FIG. 2C. Referring to FIGS. 10B and 10C, the main display area MDA (see FIG. 10A) and the subsidiary display area SDA (see FIG. 10A) may be attached to the cover window CW, and the second adhesive member 520 may be injected to the corner display area CDA (see FIG. 10A). In this case, the second adhesive member 520 may be injected by an injection tool such as a needle. In addition, the second adhesive member 520 may be injected through the injection hole 530.

As described above, because the display panel 10 to which the first adhesive member 510 is attached is attached to the cover window CW, and then, the second adhesive member 520, which is liquid, is injected, the corner display area CDA may be fixed to the cover window CW without forming bubbles or the like. In addition, in this case, because a step of hardening the second adhesive member 520 may not be performed, a process may be more simplified.

The second adhesive member 520 is injected to the corner display area CDA through the injection hole 530, and then, similar to FIGS. 9K and 9L, the guide film GF may be removed from the display panel 10, the display panel 10 and the cover window CW attached to each other may be hardened.

FIG. 11 is an exploded perspective view of a display apparatus 1 according to another embodiment. Hereinafter, differences from the above embodiment are mainly described.

Referring to FIG. 11, the adhesive member 500 may be arranged between the display panel 10 and the cover window CW. The adhesive member 500 may be provided in plurality. The plurality of adhesive members 500 may be different from each other.

In an embodiment, the adhesive member 500 may include the first adhesive member 510 and the second adhesive member 520 that is different from the first adhesive member 510.

The first adhesive member 510 may be arranged to correspond to a flat portion of one side (a side in a +z-direction of FIG. 10) of the display panel 10, for example, the main display area MDA. The second adhesive member 520 may be arranged to correspond to a curved portion of one side of the display panel 10, for example, the subsidiary display area SDA and the corner display area CDA. In this case, the first adhesive member 510 may be arranged to be surrounded by the second adhesive member 520.

The first adhesive member 510 may be a solid or semi-solid OCA film. In addition, the second adhesive member 520 may be a liquid OCR.

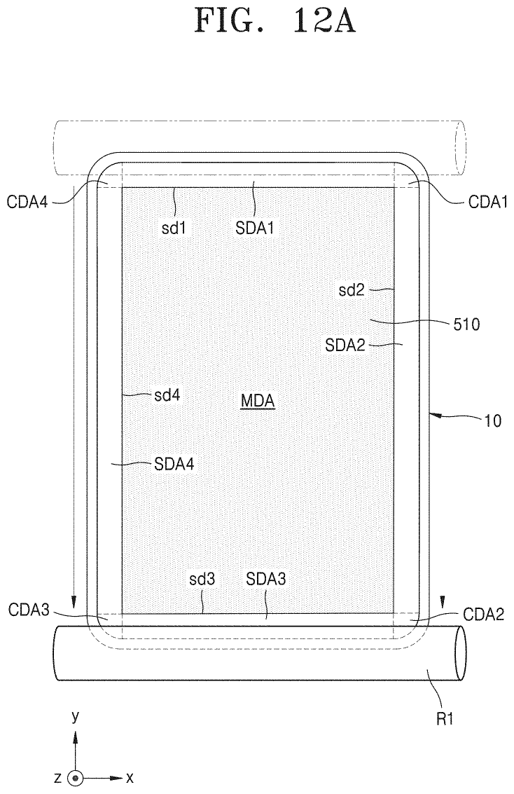

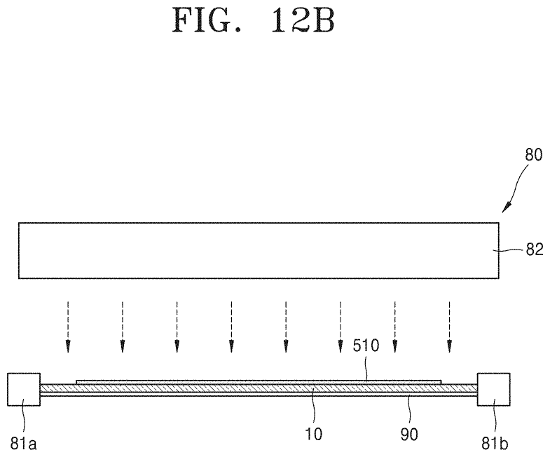

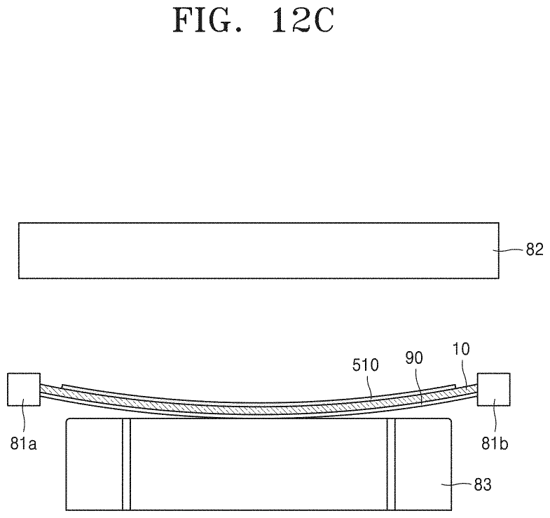

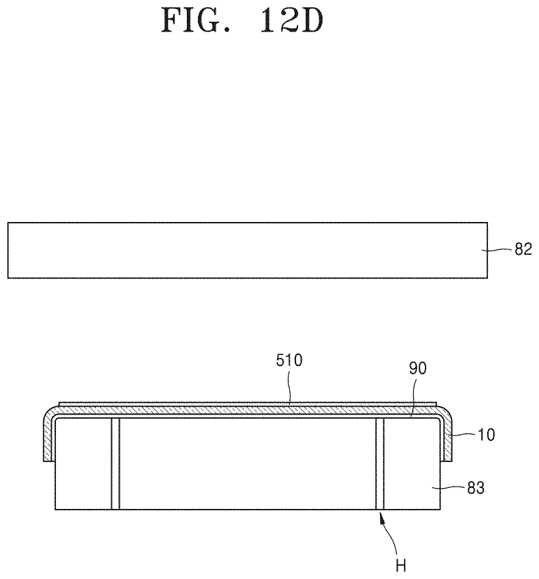

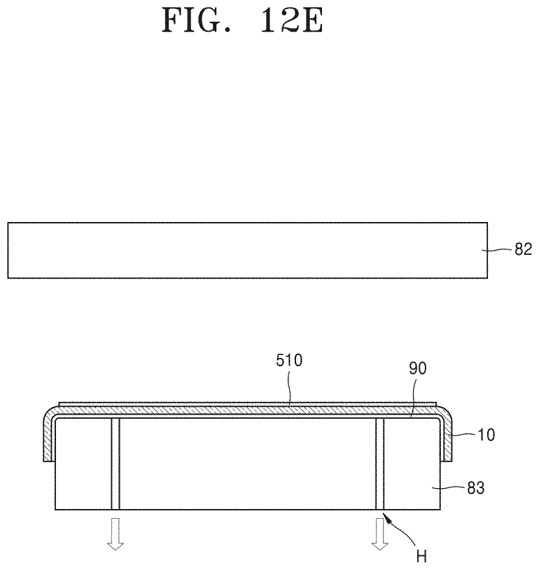

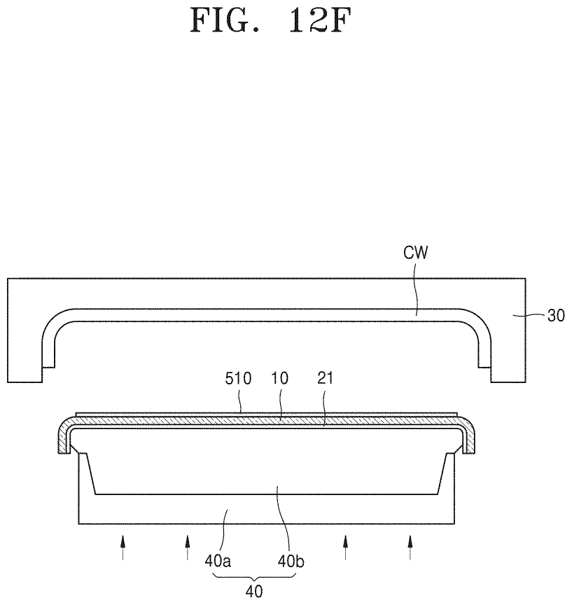

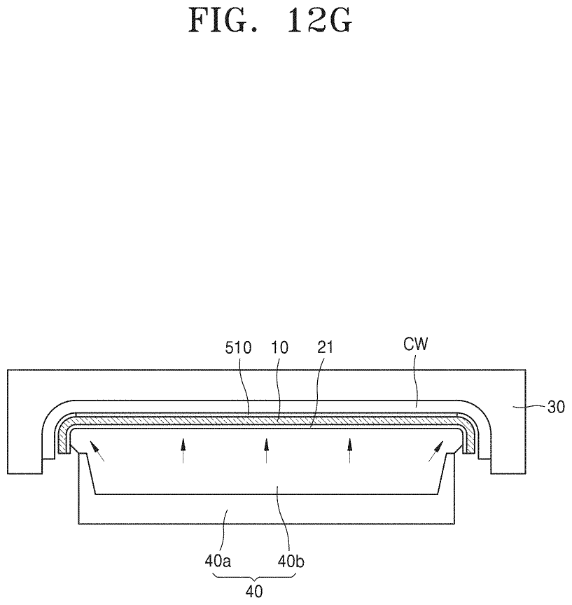

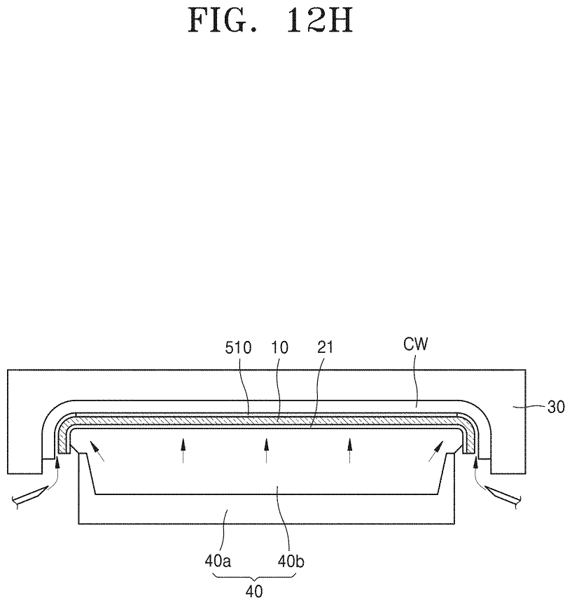

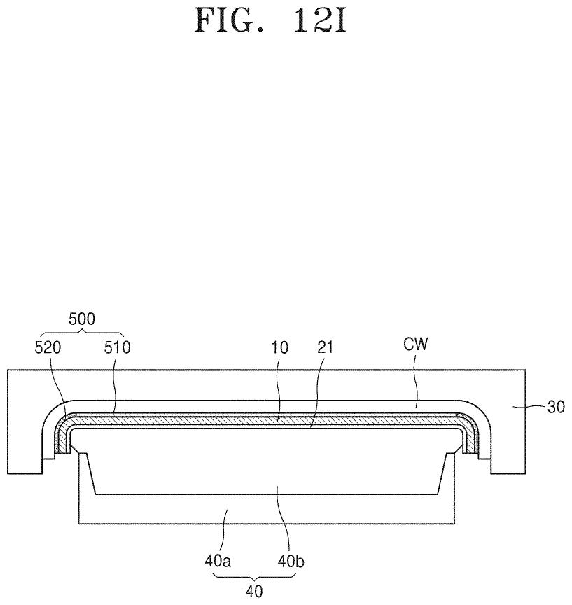

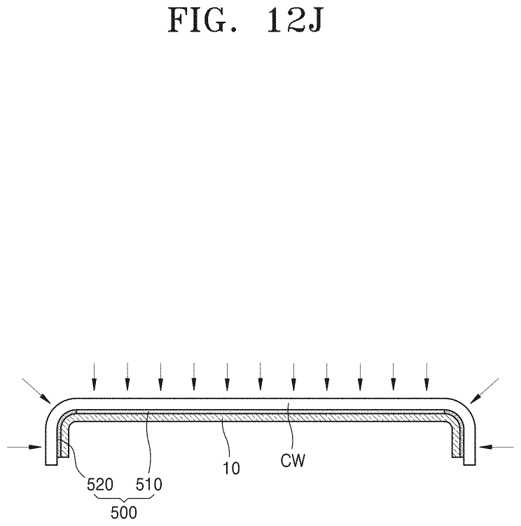

FIGS. 12A to 12J are views showing a method of manufacturing a display apparatus according to another embodiment. Specifically, unlike the method of manufacturing a display apparatus described above referring to FIG. 9A to 9L, a method of forming a display panel by using heat without using the guide film is shown in FIGS. 12A to 12J.

Though the method of manufacturing a display apparatus according to the present embodiment may be a method of manufacturing the display apparatus 1 shown in FIG. 11, the method of the invention is not limited thereto.

Referring to FIG. 12A, the first adhesive member 510 is attached to the front side (e.g., a side in the z-direction of FIG. 12A) of the display panel 10. Specifically, the first adhesive member 510 may be attached to correspond to the main display area MDA. In an embodiment, the first adhesive member 510 may be the first adhesive member 510 described above, particularly, the first adhesive member 510 shown in FIG. 11. In this case, before the first adhesive member 510 is attached, a thermoforming film 90 may be attached to the backside of the display panel 10. This is described below.

Referring to FIG. 12B, an apparatus 80 for manufacturing a display apparatus may include a first clamp 81a, a second clamp 81b, an operating heater 82, and a forming frame 83 (see FIG. 12C).

The first clamp 81a and the second clamp 81b may fix or move an object. The operating heater 82 may apply heat to the object. The forming frame 83 may transform the shape of the object. The forming frame 83 may define a plurality of holes H therein. Air or the like may move through the plurality of holes H.

First, the thermoforming film 90 is attached to the display panel 10. The thermoforming film 90 may be attached to the backside of the display panel 10. The thermoforming film 90 may be a resin film of a transparent sheet form including a polymer compound such as polyethylene terephthalate (“PET”), polymethylmethacrylate (PMMA), polyurethane (“PU”), polycarbonate (PC), or the like. The first adhesive member 510 is attached to a real side of the display panel 10 facing a side of the display panel 10 to which the thermoforming film 90 is attached, that is, the front side of the display panel 10.

Next, two opposite ends of the display panel 10 to which the thermoforming film 90 and the first adhesive member 510 are attached are fixed by using the first clamp 81a and the second clamp 81b. The display panel 10 to which the thermoforming film 90 is attached is set to a stretched state such that the display panel 10 is pulled tautly by using the first clamp 81a and the second clamp 81b. Next, the thermoforming film 90 is heated by using the operating heater 82. Heating temperature may be within a temperature range forming a softening point of the thermoforming film 90. When heat is applied to the thermoforming film 90, the modulus of the thermoforming film 90 is reduced and transformation of the thermoforming film 90 becomes easy. On the contrary, when the thermoforming film 90 is cooled down, the modulus of the thermoforming film 90 increases, and transformation of the thermoforming film 90 becomes difficult.

Referring to FIG. 12C, the thermoforming film 90 softened by preheating is shown. Referring to FIGS. 12C and 12D, as the first clamp 81a and the second clamp 81b descend, the thermoforming film 90 in a stretched state may contact the surface of the forming frame 83. As another example, the first clamp 81a and the second clamp 81b are stationary, and as the forming frame 83 ascends, the thermoforming film 90 may contact the surface of the forming frame 83.

Next, referring to FIG. 12E, air between the thermoforming film 90 and the forming frame 83 is discharged through the plurality of holes H formed in the forming frame 83, and a vacuum state may be formed. As a result, the thermoforming film 90 may be closely attached to the surface of the forming frame 83, and forming may be performed. In addition, as the thermoforming film 90 is transformed, the display panel 10 and the first adhesive member 510 attached to the display panel 10 may be also transformed. In addition, after the shape of the display panel 10 is transformed, the thermoforming film 90 may not be removed from the display panel 10, but the embodiment is not limited thereto. As an example, after the shape of the display panel 10 is transformed, the thermoforming film 90 may be removed from the display panel 10.

In the case where the display panel 10 is formed by applying heat to the thermoforming film 90, the front side of the display panel 10 may be transformed simultaneously by the forming frame 83 of a desired shape. Particularly, in the case where the shape of the corner display area CDA arranged in the corner of the display panel 10 is transformed, various forces such as contract force, extension force, or the like are applied to the corner display area CDA. When heat and the forming frame 83 are used, the shape of the corner display area CDA may be transformed at a time.

Referring to FIGS. 12F and 12G, the display panel 10 and the cover window CW that are formed may be attached to each other. In this case, because the display panel 10 is formed to a desired shape by using the forming frame 83 (See FIGS. 12C to 12E), the pad portion 40 may simply press the display panel 10 and the cover window CW. Accordingly, the main display area MDA may be attached to the cover window CW by the first adhesive member 510 attached to the display panel 10.

Next, referring to FIGS. 12H and 121, the second adhesive member 520 may be injected to the subsidiary display area SDA (See FIG. 12A) and the corner display area CDA (See FIG. 12A). In this case, the second adhesive member 520 may be injected by an injection tool such as a needle. Accordingly, the curved portion of the display panel 10, that is, the subsidiary display area SDA and the corner display area CDA, may be attached to the curved portion of the cover window CW without forming wrinkles or bubbles.

Referring to FIG. 12J, a step of hardening the cover window CW and the display panel 10 attached to each other is performed. As an example, the hardening may be performed by irradiating an ultraviolet ray to the cover window CW and the display panel 10. In this case, the adhesive member 500 may be hardened, and when high temperature and/or high pressure are applied to the cover window CW and the display panel 10, bubbles or the like formed inside the adhesive member 500 may come out.

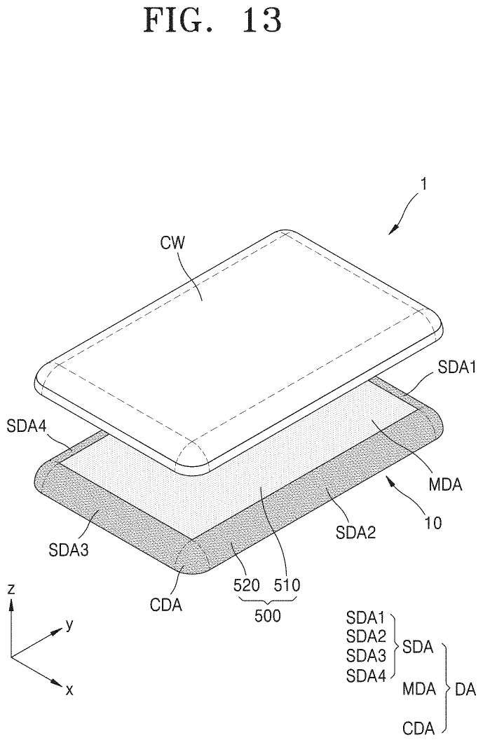

FIG. 13 is an exploded perspective view of a display apparatus 1 according to still another embodiment. Hereinafter, differences from the above embodiment are mainly described.

Referring to FIG. 13, the display apparatus 1 may be similar to the display apparatus of FIG. 11. The first adhesive member 510 may be arranged to correspond to a flat portion of one side (a side in the +z-direction of FIG. 10) of the display panel 10, for example, the main display area MDA. The second adhesive member 520 may be arranged to correspond to a curved portion of one side of the display panel 10, for example, the subsidiary display area SDA and the corner display area CDA.

In this case, the first adhesive member 510 may be a liquid OCR. In addition, the second adhesive member 520 may be a liquid OCR. The first adhesive member 510 may have a viscosity different from a viscosity of the second adhesive member 520. In an embodiment, the viscosity of the first adhesive member 510 may be greater than the viscosity of the second adhesive member 520. As an example, the viscosity of the first adhesive member 510 may be about 8000 centipoises (cps), and the viscosity of the second adhesive member 520 may be about 100 cps. As described below, this viscosity difference may prevent defects while the cover window CW is attached to the display panel 10.

FIGS. 14A and 14B are views showing a method of manufacturing a display apparatus according to still another embodiment.

Because the method of manufacturing a display apparatus according to the present embodiment is similar to the method of manufacturing a display apparatus described with reference to FIG. 12, differences are mainly described below.

The method of manufacturing a display apparatus according to the present embodiment may be a method of manufacturing the display apparatus 1 shown in FIG. 13.

Referring to FIGS. 14A and 14B, the first adhesive member 510 is arranged on the front side (e.g., a side in a z-direction of FIG. 14A) of the display panel 10. In an embodiment, the first adhesive member 510 may be the first adhesive member 510 shown in FIG. 13. Specifically, the first adhesive member 510 may be arranged to correspond to the main display area MDA. The first adhesive member 510 may include a liquid adhesive material as described above. The viscosity of the first adhesive member 510 may be greater than the viscosity of the second adhesive member 520. As an example, the viscosity of the first adhesive member 510 may be about 8000 cps. Accordingly, the first adhesive member 510 may be prevented from flowing to the subsidiary display area SDA or the corner display area CDA without remaining in the main display area MDA. In addition, as shown in FIG. 14B, the first adhesive member 510 may be coated in the main display area MDA by slit coating or inkjet printing. In this case, the thermoforming film 90 may be attached to the backside of the display panel 10 before the first adhesive member 510 is attached.

In an embodiment, the first adhesive member 510 may be coated and hardened temporarily. Temporary hardening means making the first adhesive member 510 in a higher viscosity state than that of liquid by hardening the first adhesive member 510 more or less in advance, for example, a state such as gel. In an embodiment, temporary hardening may be performed by irradiating an ultraviolet ray.

Next, similar to steps shown in FIGS. 12B to 12J, steps may be performed. That is, the display panel 10 may be formed to a desired shape by softening the thermoforming film 90 and using the forming frame 83. The display panel 10 that is formed is attached to the cover window CW, and the second adhesive member 520 may be injected to the subsidiary display area SDA and the corner display area CDA. Next, hardening may be performed by irradiating an ultraviolet ray to the cover window CW and the display panel 10.

In this case, the viscosity of the second adhesive member 520 may be less than the viscosity of the first adhesive member 510. The viscosity of the second adhesive member 520 may be about 100 cps. Accordingly, the second adhesive member 520 may be injected fast without resistance corresponding to viscosity while injected to the subsidiary display area SDA and the corner display area CDA.

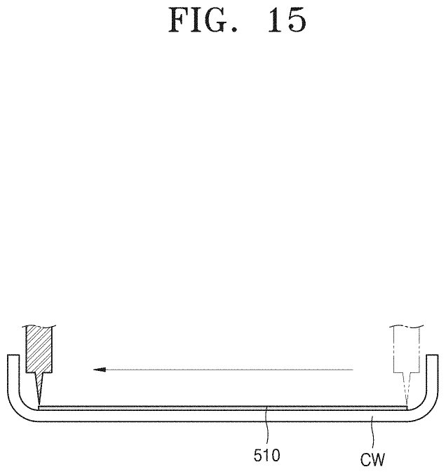

FIG. 15 is a view showing a method of manufacturing a display apparatus according to yet another embodiment. Because the present embodiment is similar to the method of manufacturing a display apparatus described with reference to FIG. 14, differences are mainly described below.

Referring to FIG. 15, the first adhesive member 510 may be coated on the cover window CW, particularly, a flat portion of the cover window CW, not the display panel 10. The flat portion may be a region attached to the main display area MDA of the display panel 10. Even in this case, the first adhesive member 510, which is liquid, may be coated by using slit-coating or inkjet printing.

In an embodiment, the first adhesive member 510 may be coated and hardened temporarily. As an example, temporary hardening may be performed by irradiating an ultraviolet ray.

Next, similar to the steps shown in FIGS. 12B to 12J, steps may be performed. That is, the display panel 10 may be formed to a desired shape by softening the thermoforming film 90 and using the forming frame 83. In this case, the first adhesive member 510 is not arranged on the display panel 10. The display panel that is formed may be attached to the cover window CW through the first adhesive member 510 coated to the cover window CW, and the second adhesive member 520 may be injected to the subsidiary display area SDA and the corner display area CDA. Next, hardening may be performed by irradiating an ultraviolet ray to the cover window CW and the display panel 10 that are attached to each other.

The display apparatus according to an embodiment includes different adhesive members to facilitate attachment between the cover window and the display panel.

The method of manufacturing a display apparatus according to an embodiment may facilitate attachment between the cover window and the display panel by using different adhesive members.

Effects of the present disclosure are not limited to the above-mentioned effects and other effects not mentioned may be clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel including at least one curved portion;
a cover window covering a first surface of the display panel; and
a plurality of different adhesive members arranged between the display panel and the cover window,
wherein one of the plurality of different adhesive members is arranged to correspond to at least a portion of the curved portion of the display panel, and another of the plurality of different adhesive members is arranged to correspond to a rest of the display panel.

2. The display apparatus of claim 1, wherein the display panel includes a main display area, subsidiary display areas, and corner display areas,
wherein the subsidiary display areas are connected to sides of a periphery of the main display area, respectively, and the corner display areas are arranged between the subsidiary display areas,
wherein the plurality of different adhesive members include a first adhesive member and a second adhesive member,
wherein the first adhesive member is arranged in the main display area and the subsidiary display areas, and the second adhesive member is arranged in the corner display areas.

3. The display apparatus of claim 2, wherein the first adhesive member surrounds the second adhesive member.

4. The display apparatus of claim 3, wherein an injection hole is arranged in one side of the first adhesive member, and the second adhesive member is injected to the injection hole.

5. The display apparatus of claim 2, wherein the second adhesive member and a portion of the first adhesive member are arranged to correspond to the corner display areas.

6. The display apparatus of claim 5, wherein the first adhesive member is arranged on a periphery of the corner display areas, and the second adhesive member is arranged on a center of the corner display areas.

7. The display apparatus of claim 2, wherein the first adhesive member and the second adhesive member each are arranged in a same layer.

8. The display apparatus of claim 2, wherein the corner display area includes a plurality of strip portions, and
wherein the second adhesive member is arranged between the plurality of strip portions.

9. The display apparatus of claim 1, wherein the display panel includes a main display area, subsidiary display areas, and corner display areas,
wherein the subsidiary display areas are connected to sides of a periphery of the main display area, respectively, and the corner display areas are arranged between the subsidiary display areas,
wherein the plurality of different adhesive members include a first adhesive member and a second adhesive member,
wherein the first adhesive member is arranged in the main display area, and the second adhesive member is arranged in the subsidiary display areas and the corner display areas.

10. The display apparatus of claim 9, wherein a viscosity of the first adhesive member is greater than a viscosity of the second adhesive member.

11. The display apparatus of claim 9, further comprising a thermoforming film arranged on a second surface of the display panel opposite to the first surface.

12. A method of manufacturing a display apparatus, the method comprising:
arranging a plurality of different adhesive members between a cover window and a display panel;
aligning the display panel with the cover window such that one surface of the display panel on which the plurality of different adhesive members are arranged faces the cover window; and
attaching the cover window to the display panel.

13. The method of claim 12, wherein the arranging of the plurality of different adhesive members includes
arranging a first adhesive member of a solid type and arranging a second adhesive member of a liquid type,
wherein the plurality of different adhesive members include the first adhesive member and the second adhesive member.

14. The method of claim 12, wherein the display panel includes a main display area, subsidiary display areas, and corner display areas,
wherein the subsidiary display areas are connected to sides of a periphery of the main display area, respectively, and the corner display areas are arranged between the subsidiary display areas,
wherein the arranging of the plurality of different adhesive members includes:
arranging a first adhesive member in a portion of the main display area, the subsidiary display areas, and the corner display areas, and
arranging a second adhesive member in the rest of the main display area, the subsidiary display areas, and the corner display areas,
wherein the plurality of different adhesive members include the first adhesive member and the second adhesive member.

15. The method of claim 14, wherein the arranging of the second adhesive member includes:
injecting the second adhesive member after arranging the first adhesive member, and attaching the cover window to the display panel.

16. The method of claim 14, wherein the arranging of the second adhesive member includes:
coating the second adhesive member on a center of the corner display area surrounded by the first adhesive member after arranging the first adhesive member on a periphery of the corner display area.

17. The method of claim 16, further comprising hardening temporarily the first adhesive member and the second adhesive member.

18. A method of manufacturing a display apparatus, the method comprising:
arranging a plurality of different adhesive members between a cover window and a display panel;
arranging a thermoforming film on a first surface of the display panel opposite to a second surface of the display panel that faces the cover window;
transforming a shape of the display panel;
aligning the display panel with the cover window such that the second surface of the display panel on which the plurality of different adhesive members are arranged faces the cover window; and
attaching the cover window to the display panel.

19. The method of claim 18, wherein the transforming of the shape of the display panel includes softening the thermoforming film by raising a temperature of the thermoforming film.

20. The method of claim 18, wherein the arranging of the plurality of different adhesive members includes:
arranging a first adhesive member in one region of the display panel before attaching the cover window to the display panel; and
arranging a second adhesive member to the rest region of the display panel other than the one region after attaching the cover window to the display panel,
wherein the plurality of different adhesive members include the first adhesive member and the second adhesive member.

21. The method of claim 18, wherein the arranging of the plurality of different adhesive members includes arranging the plurality of different adhesive members on one side of the cover window.
